(19) United States
(12) Patent Application Publication
(10) Pub. No.: US 2025/0185307 A1
(43) Pub. Date: Jun. 5, 2025

(54) MULTIPLE THRESHOLD STACKED FIELD EFFECT TRANSISTORS

(71) Applicant: International Business Machines Corporation, Armonk, NY (US)

(72) Inventors: Ruilong Xie, Niskayuna, NY (US); Shay Reboh, Guilderland, NY (US); Julien Frougier, Albany, NY (US); Nicolas Jean Loubet, Guilderland, NY (US)

(21) Appl. No.: 18/529,467

(22) Filed: Dec. 5, 2023

(51) Int. Cl. H01L 29/788; H01L 27/088; H01L 27/092; H01L 29/66; H01L 29/78

(52) U.S. Cl. CPC H10D 30/687; H10D 30/024; H10D 30/6211; H10D 64/017; H10D 64/021; H10D 84/834; H10D 84/853

(57) ABSTRACT

Embodiments are disclosed for a semiconductor structure that includes a first stacked field effect transistor (FET) configured as a shared gate device, and a second stacked FET configured to operate as two independent gate devices. The first stacked FET includes a first top FET having a first top work-function metal (WFM) and a first bottom FET having a first bottom WFM. Further, the first top WFM and the first bottom WFM are connected through shared gate connectors disposed on either side of a middle dielectric isolation (MDI) layer. Further, the second stacked FET includes a second top FET having a second top WFM and a second bottom FET having a second bottom WFM. Further, the second top WFM and the second bottom WFM are separated by the MDI layer and a pair of spacer shoulders disposed on either side of the MDI layer.

### BACKGROUND

The present invention generally relates to semiconductor structures, and more particularly to multiple threshold voltages for stacked field effect transistor (FET) semiconductor structures.

Integrated circuit (IC) chips are formed on semiconductor wafers at increasingly smaller scale. In current technology nodes, such as 7, 10 and 14 nanometer (nm) technologies, transistor devices are constructed as three-dimensional (3D) fin FET (FINFET) structures. However, chipmakers face a myriad of challenges at 5 nm, 3 nm and beyond. Currently, traditional chip scaling continues to slow as process complexities and costs escalate at each node.

A potential solution to this chip scaling problem is gate all around technology. One example of a complex gate all around technology is a stacked FET where nFET and pFET nanowires/nanosheets are vertically stacked on top of each other.

In a stacked FET semiconductor, it can be useful to have a stack of transistors having different threshold voltages. More specifically, stacked FET semiconductors having multiple threshold voltages may be useful for high performance, power savings, and the like, potentially in combinations. However, in a conventional monolithic stacked FET approach, it can be challenging to perform work-function patterning between the top and bottom channels in the stack. For example, it is challenging to remove work function metal (WFM) from the top transistor if not removing WFM from the bottom transistor. More specifically, the over etch used to clean the WFM between nanosheets could cause a relatively severe undercut into the bottom transistor. While it is possible to use a sacrificial material to protect the bottom transistor, the over etch may still undercut into the bottom transistor.

### SUMMARY

Embodiments are disclosed for a semiconductor structure that includes a first stacked field effect transistor (FET) configured as a shared gate device, and a second stacked FET configured to operate as two independent gate devices. The first stacked FET includes a first top FET having a first top work-function metal (WFM) and a first bottom FET having a first bottom WFM. Further, the first top WFM and the first bottom WFM are connected through shared gate connectors disposed on either side of a middle dielectric isolation (MDI) layer. Further, the second stacked FET includes a second top FET having a second top WFM and a second bottom FET having a second bottom WFM. Further, the second top WFM and the second bottom WFM are separated by the MDI layer and a pair of spacer shoulders disposed on either side of the MDI layer. Such embodiments can provide stacked FET semiconductors with improved performance and power savings, without undercutting the transistor devices.

Embodiments are disclosed for a semiconductor structure that includes a first stacked field effect transistor (FET) configured as a shared gate device, and a second stacked FET configured to operate as two independent gate devices. The first stacked FET includes a first top FET having a first top work-function metal (WFM) and a first bottom FET having a first bottom WFM. Further, the first top WFM and the first bottom WFM are connected through shared gate connectors disposed on either side of a middle dielectric isolation (MDI) layer. Further, the second stacked FET includes a second top FET having a second top WFM and a second bottom FET having a second bottom WFM. Further, the second top WFM and the second bottom WFM are separated by the MDI layer and a pair of spacer shoulders disposed on either side of the MDI layer. Additionally, the first top WFM is formed by depositing the first top WFM through a frontside opening, wherein the frontside opening does not comprise a gate dielectric, the second top FET is formed by depositing the second top WFM through the frontside opening. Such embodiments can provide stacked FET semiconductors with improved performance and power savings, without undercutting the transistor devices.

Embodiments are disclosed for a semiconductor structure that includes a first stacked field effect transistor (FET) configured as a shared gate device, and a second stacked FET configured to operate as two independent gate devices. The first stacked FET includes a first top FET having a first top work-function metal (WFM) and a first bottom FET having a first bottom WFM. Further, the first top WFM and the first bottom WFM are connected through shared gate connectors disposed on either side of a middle dielectric isolation (MDI) layer. Further, the second stacked FET includes a second top FET having a second top WFM and a second bottom FET having a second bottom WFM. Further, the second top WFM and the second bottom WFM are separated by the MDI layer and a pair of spacer shoulders disposed on either side of the MDI layer. Additionally, the first bottom WFM is formed by depositing the first bottom WFM through a backside opening, wherein the backside opening does not include a gate dielectric. Further, the second bottom FET is formed by depositing the second bottom WFM through the backside opening. Such embodiments can provide stacked FET semiconductors with improved performance and power savings, without undercutting the transistor devices.

Embodiments are disclosed for a method of fabricating a semiconductor structure. The method includes forming a bottom dielectric isolation (BDI) layer. Additionally, the method includes forming a middle dielectric isolation (MDI) layer. Further, the method includes performing an interlayer dielectric fill that prevents access to the BDI layer and MDI layer. Additionally, the method includes performing a fin reveal that provides access to the MDI layer. Further, the method includes performing a selective MDI indentation on the MDI layer to form a pair of MDI divots. Additionally, each of the pair of MDI divots is disposed on either end of the MDI layer. Further, the method includes performing an MDI indentation fill to form a pair of spacer shoulders on the MDI layer. Additionally, the MDI indentation fill fills the pair of MDI divots with a spacer shoulder dielectric that is different than a dielectric of the MDI. Further, the method includes performing a selective channel indentation of a plurality of channel layers of the semiconductor structure to form a pair of channel divots on each of the plurality of channel layers. Additionally, each of the pair of channel divots is disposed on either end of each of the plurality of channel layers. Further, the method includes performing a second fin reveal that provides access to the BDI layer. Additionally, the method includes performing a selective BDI indentation to form a pair of BDI divots, wherein each of the pair of BDI divots is disposed on either end of the BDI layer. Such embodiments can provide stacked FET semiconductors with improved performance and power savings, without undercutting the transistor devices.

The present Summary is not intended to illustrate each aspect of, every implementation of, and/or every embodiment of the present disclosure. These and other features and advantages will become apparent from the following detailed description of the present embodiment(s), taken in conjunction with the accompanying drawings.

### BRIEF DESCRIPTION OF THE DRAWINGS

The drawings included in the present application are incorporated into, and form part of, the specification. They illustrate embodiments of the present disclosure and, along with the description, serve to explain the principles of the disclosure. The drawings are illustrative of certain embodiments and do not limit the disclosure.

FIG. 1-1 is a cross-sectional view and a top view of semiconductor structures during intermediate steps of a method for forming multiple threshold voltage stacked field effect transistor (FET) semiconductor structures, in accordance with some embodiments of the present disclosure.

FIG. 1-2 is a cross-sectional view and a top view of semiconductor structures during intermediate steps of a method for forming multiple threshold voltage stacked FET semiconductor structures, in accordance with some embodiments of the present disclosure.

FIG. 1-3 is a cross-sectional view and a top view of semiconductor structures during intermediate steps of a method for forming multiple threshold voltage stacked FET semiconductor structures, in accordance with some embodiments of the present disclosure.

FIG. 1-4 is a cross-sectional view and a top view of semiconductor structures during intermediate steps of a method for forming multiple threshold voltage stacked FET semiconductor structures, in accordance with some embodiments of the present disclosure.

FIG. 1-5 is a cross-sectional view and a top view of semiconductor structures during intermediate steps of a method for forming multiple threshold voltage stacked FET semiconductor structures, in accordance with some embodiments of the present disclosure.

FIG. 1-6 is a cross-sectional view and a top view of semiconductor structures during intermediate steps of a method for forming multiple threshold voltage stacked FET semiconductor structures, in accordance with some embodiments of the present disclosure.

FIG. 1-7 is a cross-sectional view and a top view of semiconductor structures during intermediate steps of a method for forming multiple threshold voltage stacked FET semiconductor structures, in accordance with some embodiments of the present disclosure.

FIG. 1-8 is a cross-sectional view and a top view of semiconductor structures during intermediate steps of a method for forming multiple threshold voltage stacked FET semiconductor structures, in accordance with some embodiments of the present disclosure.

FIG. 1-9 is a cross-sectional view and a top view of semiconductor structures during intermediate steps of a method for forming multiple threshold voltage stacked FET semiconductor structures, in accordance with some embodiments of the present disclosure.

FIG. 1-10 is a cross-sectional view and a top view of semiconductor structures during intermediate steps of a method for forming multiple threshold voltage stacked FET semiconductor structures, in accordance with some embodiments of the present disclosure.

FIG. 1-11 is a cross-sectional view and a top view of semiconductor structures during intermediate steps of a method for forming multiple threshold voltage stacked FET semiconductor structures, in accordance with some embodiments of the present disclosure.

FIG. 1-12 is a cross-sectional view and a top view of semiconductor structures during intermediate steps of a method for forming multiple threshold voltage stacked FET semiconductor structures, in accordance with some embodiments of the present disclosure.

FIG. 1-13 is a cross-sectional view and a top view of semiconductor structures during intermediate steps of a method for forming multiple threshold voltage stacked FET semiconductor structures, in accordance with some embodiments of the present disclosure.

FIG. 1-14 is a cross-sectional view and a top view of semiconductor structures during intermediate steps of a method for forming multiple threshold voltage stacked FET semiconductor structures, in accordance with some embodiments of the present disclosure.

FIG. 1-15 is a cross-sectional view and a top view of semiconductor structures during intermediate steps of a method for forming multiple threshold voltage stacked FET semiconductor structures, in accordance with some embodiments of the present disclosure.

FIG. 1-16 is a cross-sectional view and a top view of semiconductor structures during intermediate steps of a method for forming multiple threshold voltage stacked FET semiconductor structures, in accordance with some embodiments of the present disclosure.

FIG. 1-17 is a cross-sectional view and a top view of semiconductor structures during intermediate steps of a method for forming multiple threshold voltage stacked FET semiconductor structures, in accordance with some embodiments of the present disclosure.

FIG. 1-18-1 is a cross-sectional view and a top view of semiconductor structures during intermediate steps of a method for forming multiple threshold voltage stacked FET semiconductor structures, in accordance with some embodiments of the present disclosure.

FIG. 1-18-2 is a cross-sectional view and a top view of semiconductor structures during intermediate steps of a method for forming multiple threshold voltage stacked FET semiconductor structures, in accordance with some embodiments of the present disclosure.

FIG. 1-19-1 is a cross-sectional view and a top view of semiconductor structures during intermediate steps of a method for forming multiple threshold voltage stacked FET semiconductor structures, in accordance with some embodiments of the present disclosure.

FIG. 1-19-2 is a cross-sectional view and a top view of semiconductor structures during intermediate steps of a method for forming multiple threshold voltage stacked FET semiconductor structures, in accordance with some embodiments of the present disclosure.

FIG. 1-20-1 is a cross-sectional view and a top view of semiconductor structures during intermediate steps of a method for forming multiple threshold voltage stacked FET semiconductor structures, in accordance with some embodiments of the present disclosure.

FIG. 1-20-2 is a cross-sectional view and a top view of semiconductor structures during intermediate steps of a method for forming multiple threshold voltage stacked FET semiconductor structures, in accordance with some embodiments of the present disclosure.

FIG. 1-21-1 is a cross-sectional view and a top view of semiconductor structures during intermediate steps of a method for forming multiple threshold voltage stacked FET semiconductor structures, in accordance with some embodiments of the present disclosure.

FIG. 1-21-2 is a cross-sectional view and a top view of semiconductor structures during intermediate steps of a method for forming multiple threshold voltage stacked FET semiconductor structures, in accordance with some embodiments of the present disclosure.

FIG. 1-22-1 is a cross-sectional view and a top view of semiconductor structures during intermediate steps of a method for forming multiple threshold voltage stacked FET semiconductor structures, in accordance with some embodiments of the present disclosure.

FIG. 1-22-2 is a cross-sectional view and a top view of semiconductor structures during intermediate steps of a method for forming multiple threshold voltage stacked FET semiconductor structures, in accordance with some embodiments of the present disclosure.

FIG. 1-23-1 is a cross-sectional view and a top view of semiconductor structures during intermediate steps of a method for forming multiple threshold voltage stacked FET semiconductor structures, in accordance with some embodiments of the present disclosure.

FIG. 1-23-2 is a cross-sectional view and a top view of semiconductor structures during intermediate steps of a method for forming multiple threshold voltage stacked FET semiconductor structures, in accordance with some embodiments of the present disclosure.

FIG. 1-24-1 is a cross-sectional view and a top view of semiconductor structures during intermediate steps of a method for forming multiple threshold voltage stacked FET semiconductor structures, in accordance with some embodiments of the present disclosure.

FIG. 1-24-2 is a cross-sectional view and a top view of semiconductor structures during intermediate steps of a method for forming multiple threshold voltage stacked FET semiconductor structures, in accordance with some embodiments of the present disclosure.

FIG. 1-25-1 is a cross-sectional view and a top view of semiconductor structures during intermediate steps of a method for forming multiple threshold voltage stacked FET semiconductor structures, in accordance with some embodiments of the present disclosure.

FIG. 1-25-2 is a cross-sectional view and a top view of semiconductor structures during intermediate steps of a method for forming multiple threshold voltage stacked FET semiconductor structures, in accordance with some embodiments of the present disclosure.

FIG. 1-26-1 is a cross-sectional view and a top view of semiconductor structures during intermediate steps of a method for forming multiple threshold voltage stacked FET semiconductor structures, in accordance with some embodiments of the present disclosure.

FIG. 1-26-2 is a cross-sectional view and a top view of semiconductor structures during intermediate steps of a method for forming multiple threshold voltage stacked FET semiconductor structures, in accordance with some embodiments of the present disclosure.

FIGS. 2-1 through 2-4 represent a process flow chart of a method for forming multiple threshold voltage stacked FET semiconductor structures, in accordance with some embodiments of the present disclosure.

While the present disclosure is amenable to various modifications and alternative forms, specifics thereof have been shown by way of example in the drawings and will be described in detail. It should be understood, however, that the intention is not to limit the present disclosure to the particular embodiments described. On the contrary, the intention is to cover all modifications, equivalents, and alternatives falling within the spirit and scope of the present disclosure.

### DETAILED DESCRIPTION

Example 1 is a semiconductor structure. The semiconductor structure includes a first stacked field effect transistor (FET) configured to operate as a shared gate device, and comprising: a first top FET comprising a first top work-function metal (WFM); and a first bottom FET comprising a first bottom WFM, where the first top WFM and the first bottom WFM are connected through a pair of shared gate connectors disposed on either side of a middle dielectric isolation (MDI) layer; and a second stacked FET configured to operate as two independent gate devices: a second top FET comprising a second top WFM; and a second bottom FET comprising a second bottom WFM, where the second top WFM and the second bottom WFM are separated by the MDI layer and a pair of spacer shoulders disposed on either side of the MDI layer.

Example 2 includes the semiconductor structure of example 1, including or excluding optional features. In this example, the semiconductor structure includes a backside contact for the second bottom FET.

Example 3 includes the semiconductor structure of any one of examples 1 to 2, including or excluding optional features. In this example, the semiconductor structure includes a bottom dielectric isolation (BDI) layer composed of a same dielectric as the MDI layer.

Example 4 includes the semiconductor structure of any one of examples 1 to 3, including or excluding optional features. In this example, the spacer shoulders comprise a dielectric different from a dielectric of the MDI layer.

Example 5 is a semiconductor structure. The semiconductor structure includes a first stacked field effect transistor (FET) configured to operate as a shared gate device, and comprising: a first top FET comprising a first top work-function metal (WFM); and a first bottom FET comprising a first bottom WFM, where the first top WFM and the first bottom WFM are connected through a pair of shared gate connectors disposed on either side of a middle dielectric isolation (MDI) layer, and where the first top WFM is associated with a first top voltage threshold, and where the first bottom WFM is associated with a first bottom voltage threshold that is different than the first top voltage threshold; and a second stacked FET configured to operate as two independent gate devices: a second top FET comprising a second top WFM; and a second bottom FET comprising a second bottom WFM, where the second top WFM and the second bottom WFM are separated by the MDI layer and a pair of spacer shoulders disposed on either side of the MDI layer, where the second top WFM is associated with a second top voltage threshold, and where the second bottom WFM is associated with a second bottom voltage threshold that is different than the second top voltage threshold, and where: the first top WFM is formed by depositing the first top WFM through a frontside opening, where the frontside opening does not comprise a gate dielectric; and the second top FET is formed by depositing the second top WFM through the frontside opening.

Example 6 includes the semiconductor structure of example 5, including or excluding optional features. In this example, the first bottom WFM is formed by depositing the first bottom WFM through a backside opening, where the backside opening does not comprise a gate dielectric; and the second bottom FET is formed by depositing the second bottom WFM through the backside opening.

Example 7 includes the semiconductor structure of any one of examples 5 to 6, including or excluding optional features. In this example, the semiconductor structure includes a backside contact for the second bottom FET.

Example 8 includes the semiconductor structure of any one of examples 5 to 7, including or excluding optional features. In this example, the semiconductor structure includes a bottom dielectric isolation (BDI) layer composed of a same dielectric as the MDI layer.

Example 9 includes the semiconductor structure of any one of examples 5 to 8, including or excluding optional features. In this example, the spacer shoulders comprise a dielectric different from a dielectric of the MDI layer.

Example 10 is a method for fabricating a semiconductor structure, the method. The method includes forming a bottom dielectric isolation (BDI) layer; forming a middle dielectric isolation (MDI) layer; performing an interlayer dielectric fill that prevents access to the BDI layer and MDI layer; performing a fin reveal that provides access to the MDI layer; performing a selective MDI indentation on the MDI layer to form a pair of MDI divots, where each of the pair of MDI divots is disposed on either end of the MDI layer; and performing an MDI indentation fill to form a pair of spacer shoulders on the MDI layer, where the MDI indentation fill fills the pair of MDI divots with an spacer shoulder dielectric that is different than a dielectric of the MDI.

Example 11 includes the method of example 10, including or excluding optional features. In this example, the method includes forming a first top WFM by depositing a first top WFM through a frontside opening, where the frontside opening does not comprise a gate dielectric; and, forming a second top FET by depositing a second top WFM through the frontside opening.

Example 12 includes the method of any one of examples 10 to 11, including or excluding optional features. In this example, the method includes forming a first bottom WFM by depositing a first bottom WFM through a backside opening, where the backside opening does not comprise a gate dielectric; and, forming a second bottom FET by depositing a second bottom WFM through the backside opening.

Example 13 includes the method of any one of examples 10 to 12, including or excluding optional features. In this example, the method includes performing a selective channel indentation of a plurality of channel layers of the semiconductor structure to form a pair of channel divots on each of the plurality of channel layers, where each of the pair of channel divots is disposed on either end of each of the plurality of channel layers.

Example 14 includes the method of any one of examples 10 to 13, including or excluding optional features. In this example, the method includes performing a second fin reveal that provides access to the BDI layer; and performing a selective BDI indentation to form a pair of BDI divots, where each of the pair of BDI divots is disposed on either end of the BDI layer.

Example 15 includes the method of any one of examples 10 to 14, including or excluding optional features. In this example, the method includes performing a silicon-germanium (SiGe) epitaxial growth to generate an SiGe epitaxial that: surrounds the plurality of channels; surrounds the pair of spacer shoulders; and surrounds the BDI layer; and performing a reactive ion etching (RIE) on the SiGe epitaxial to form a plurality of fins.

Example 16 includes the method of any one of examples 10 to 15, including or excluding optional features. In this example, the method includes performing dielectric-based gate formation.

Example 17 includes the method of any one of examples 10 to 16, including or excluding optional features. In this example, the method includes performing top sacrificial layer removal from a top of the semiconductor structure; and performing replacement gate formation on the top of the semiconductor structure.

Example 18 includes the method of any one of examples 10 to 17, including or excluding optional features. In this example, the method includes performing a wafer flip; performing bottom sacrificial layer removal from a bottom of the semiconductor structure; and removing the pair of spacer shoulders for a fin to be fabricated into a shared gate device.

Example 19 includes the method of any one of examples 10 to 18, including or excluding optional features. In this example, the method includes performing backside replacement gate formation to form: the shared gate device; and an independent gate device.

Example 20 includes the method of any one of examples 10 to 19, including or excluding optional features. In this example, the method includes forming a bottom gate contact for the independent gate device.

Detailed embodiments of the claimed structures and methods are disclosed herein; however, it can be understood that the disclosed embodiments are merely illustrative of the claimed structures and methods that may be embodied in various forms. This invention may, however, be embodied in many different forms and should not be construed as limited to the example embodiments set forth herein. In the description, details of well-known features and techniques may be omitted to avoid unnecessarily obscuring the presented embodiments.

References in the specification to “one embodiment”, “an embodiment”, “an example embodiment”, etc., indicate that the embodiment described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

For purposes of the description hereinafter, the terms “upper”, “lower”, “right”, “left”, “vertical”, “horizontal”, “top”, “bottom”, and derivatives thereof shall relate to the disclosed structures and methods, as oriented in the drawing figures. It will be understood that when an element as a layer, region or substrate is referred to as being “on” or “over” another element, it can be directly on the other element or intervening elements may also be present. In contrast, when an element is referred to as being “directly on” or “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Also, the term “sub lithographic” may refer to a dimension or size less than current dimensions achievable by photolithographic processes, and the term “lithographic” may refer to a dimension or size equal to or greater than current dimensions achievable by photolithographic processes. The sub lithographic and lithographic dimensions may be determined by a person of ordinary skill in the art at the time the application is filed.

For the sake of brevity, conventional techniques related to semiconductor device and integrated circuit (IC) fabrication may or may not be described in detail herein. Moreover, the various tasks and process steps described herein can be incorporated into a more comprehensive procedure or process having additional steps or functionality not described in detail herein. In particular, various steps in the manufacture of semiconductor devices and semiconductor-based ICs are well known and so, in the interest of brevity, many conventional steps will only be mentioned briefly herein or will be omitted entirely without providing the well-known process details.

By way of background, however, a more general description of the semiconductor device fabrication processes that can be utilized in implementing one or more embodiments of the present invention will now be provided. Although specific fabrication operations used in implementing one or more embodiments of the present invention can be individually known, the described combination of operations and/or resulting structures of the present invention are unique. Thus, the unique combination of the operations described in connection with the fabrication of a semiconductor device having a dummy fin removed from within an array of tight pitch fins according to the present invention utilize a variety of individually known physical and chemical processes performed on a semiconductor (e.g., silicon) substrate, some of which are described in the immediately following paragraphs.

In general, the various processes used to form a micro-chip that will be packaged into an IC fall into four general categories, namely, film deposition, removal/etching, semiconductor doping, and patterning/lithography. Deposition is any process that grows, coats, or otherwise transfers a material onto the wafer. Available technologies include physical vapor deposition (PVD), chemical vapor deposition (CVD), electrochemical deposition (ECD), molecular beam epitaxy (MBE), and more recently, atomic layer deposition (ALD) among others. Removal/etching is any process that removes material from the wafer. Examples include etch processes (either wet or dry), and chemical-mechanical planarization (CMP), and the like. Semiconductor doping is the modification of electrical properties by doping, for example, transistor sources and drains, generally by diffusion and/or by ion implantation. These doping processes are followed by furnace annealing or by rapid thermal annealing (RTA). Annealing serves to activate the implanted dopants. Films of both conductors (e.g., poly-silicon, aluminum, copper, etc.) and insulators (e.g., various forms of silicon dioxide, silicon nitride, etc.) are used to connect and isolate transistors and their components. Selective doping of various regions of the semiconductor substrate allows the conductivity of the substrate to be changed with the application of voltage. By creating structures of these various components, millions of transistors can be built and wired together to form the complex circuitry of a modern microelectronic device.

In a stacked FET semiconductor, it can be useful to have a stack of transistors having different threshold voltages. More specifically, stacked FET semiconductors having multiple threshold voltages may be useful for high performance, power savings, and the like, potentially in combinations. However, in a conventional monolithic stacked FET approach, it can be challenging to perform work-function patterning between the top and bottom channels in the stack. For example, it is challenging to remove work function metal (WFM) from the top transistor if not removing WFM from the bottom transistor. More specifically, the over etch used to clean the WFM between nanosheets could cause a relatively severe undercut into the bottom transistor. While it is possible to use a sacrificial material to protect the bottom transistor, the over etch may still undercut into the bottom transistor.

Accordingly, some embodiments of the present disclosure provide a method to fabricate multiple threshold voltage stacked FET semiconductor structures without risk of undercut into the bottom transistors. In this way, such embodiments can provide stacked FET semiconductor structures capable of using multiple threshold voltages in each stack for improved performance, power savings, and the like without risking resources by fabricating damaged bottom transistors. However, some embodiments of the present disclosure may not achieve such advantages.

The following figures include top and cross-sectional views of example semiconductor structures produced by a fabrication process for forming multiple threshold voltage stacked FET semiconductors, in accordance with some embodiments of the present disclosure. For clarity, not all elements are labelled in these figures. Rather, representative elements are labelled, with similar elements being indicated by position, size, shape, hash lines (or lack thereof), and the like, in subsequent figures.

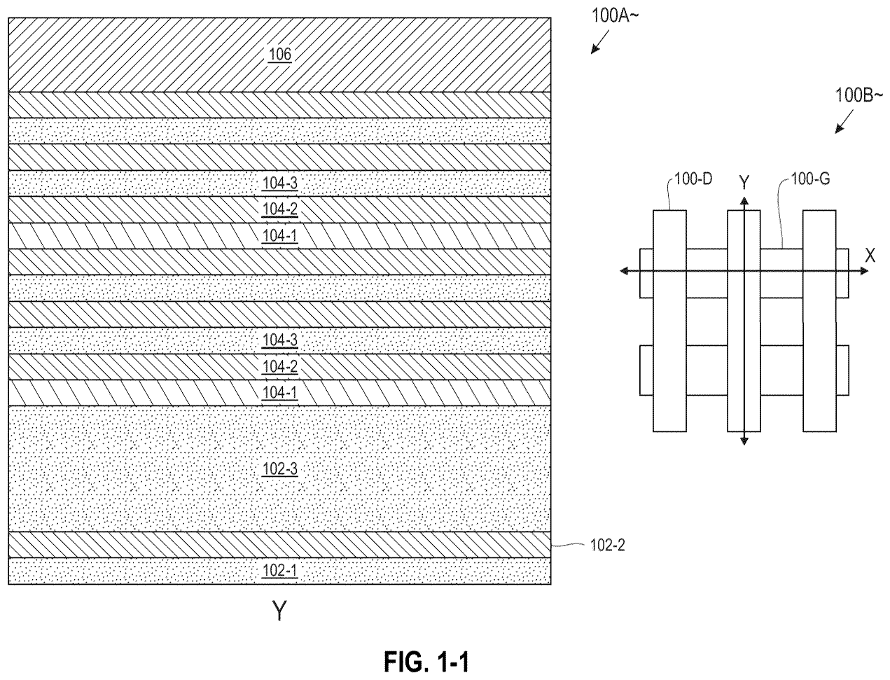

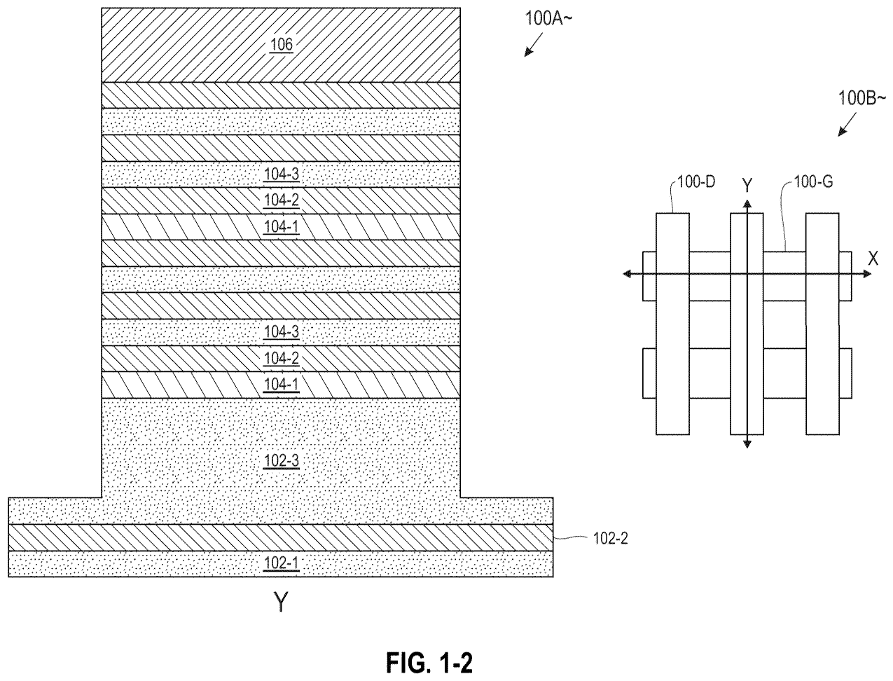

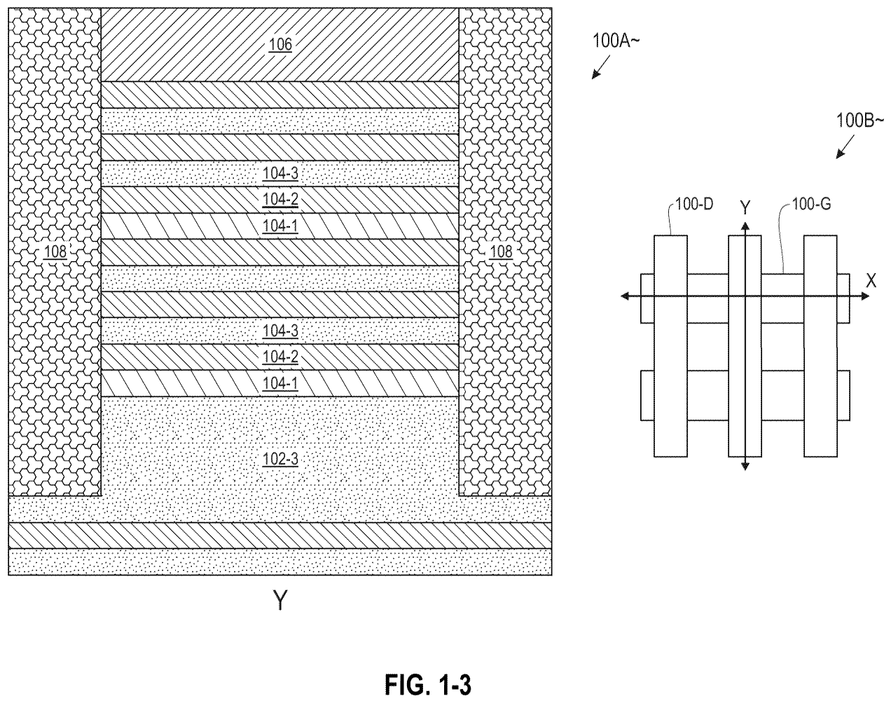

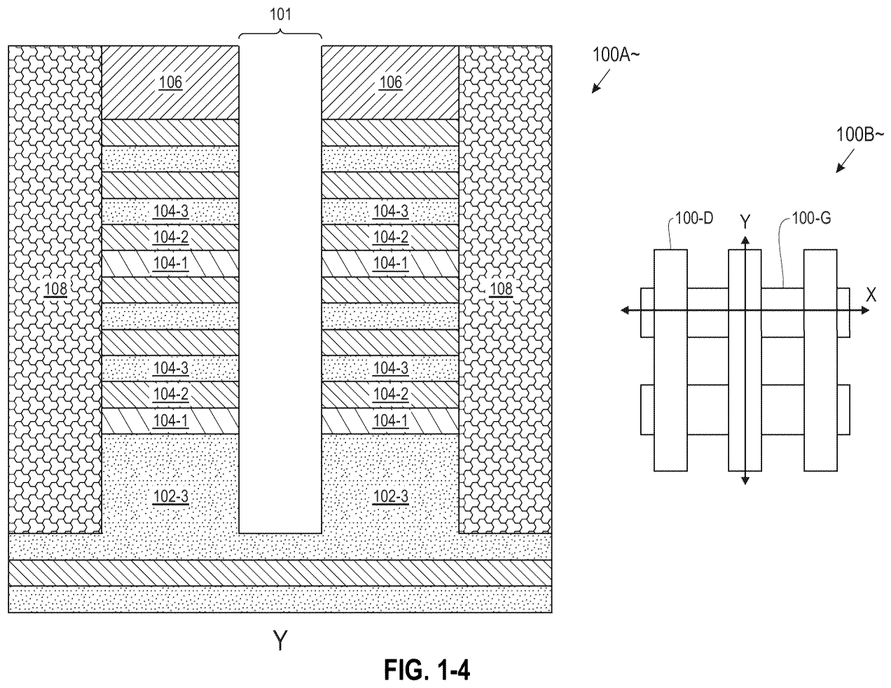

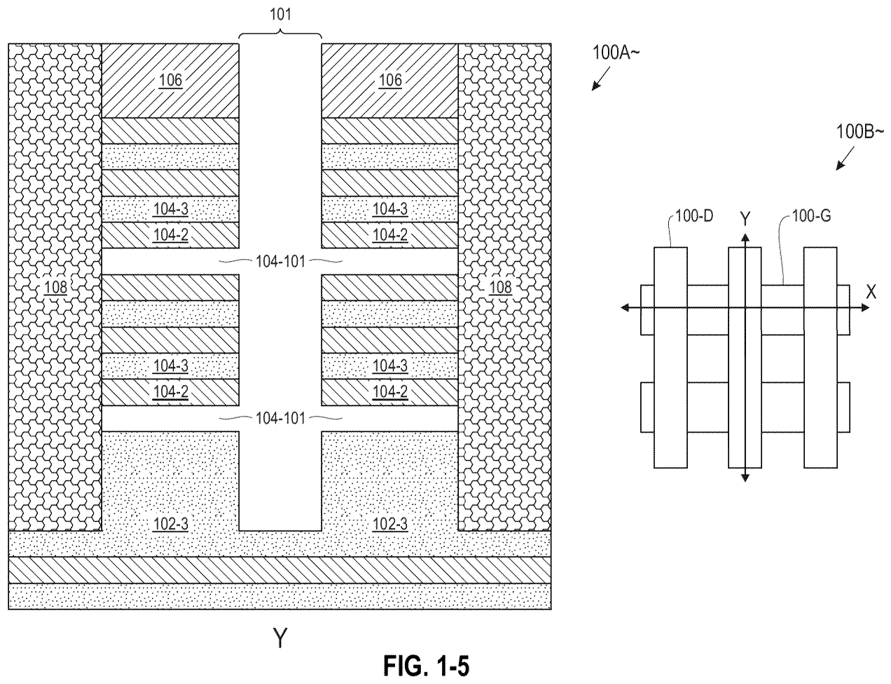

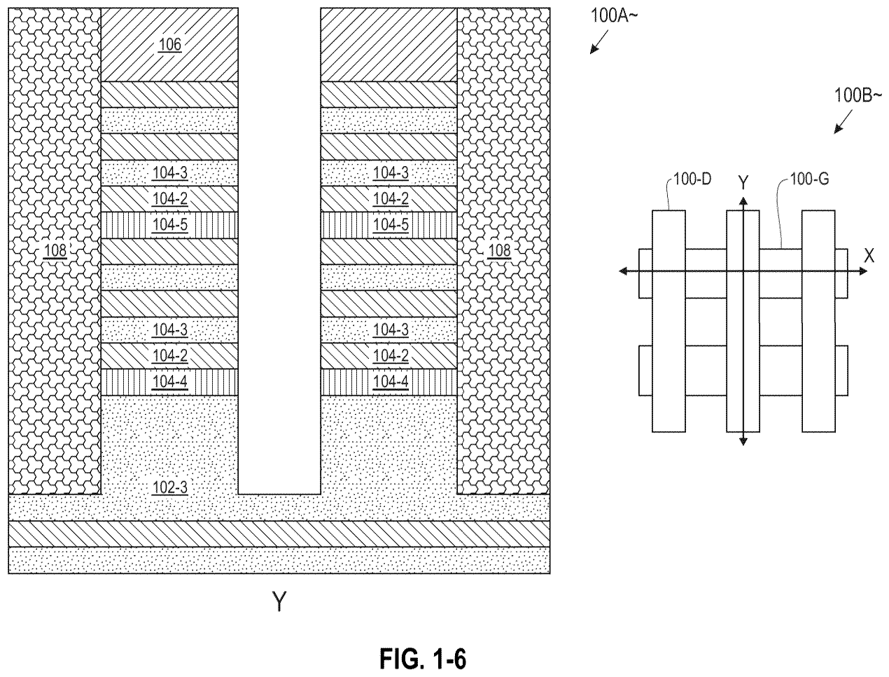

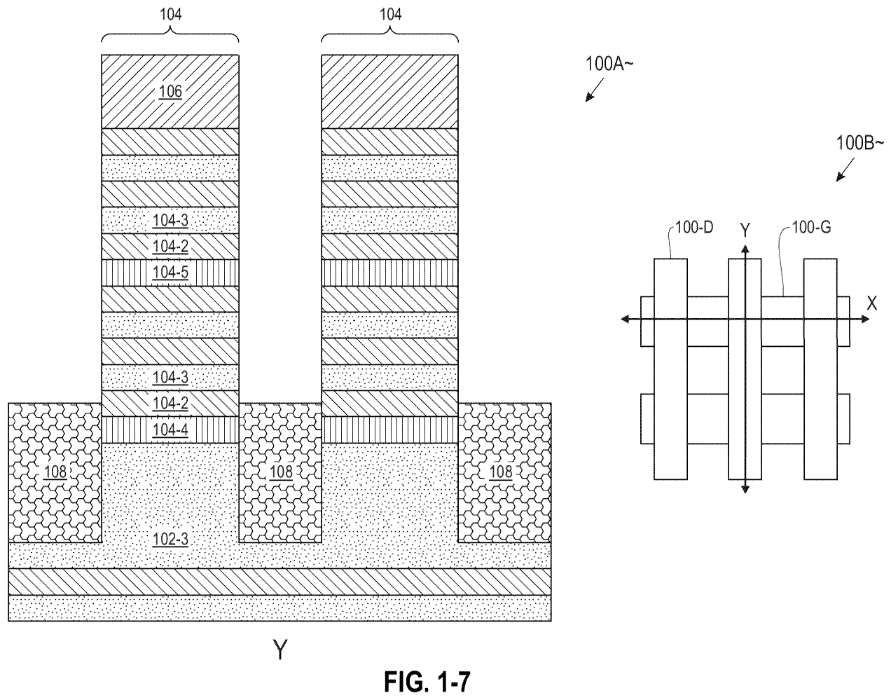

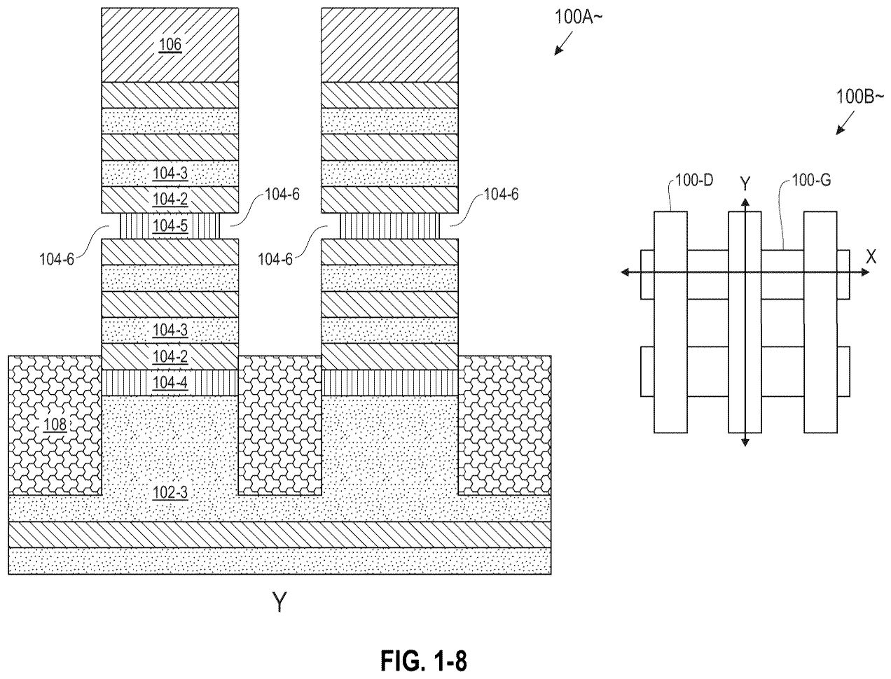

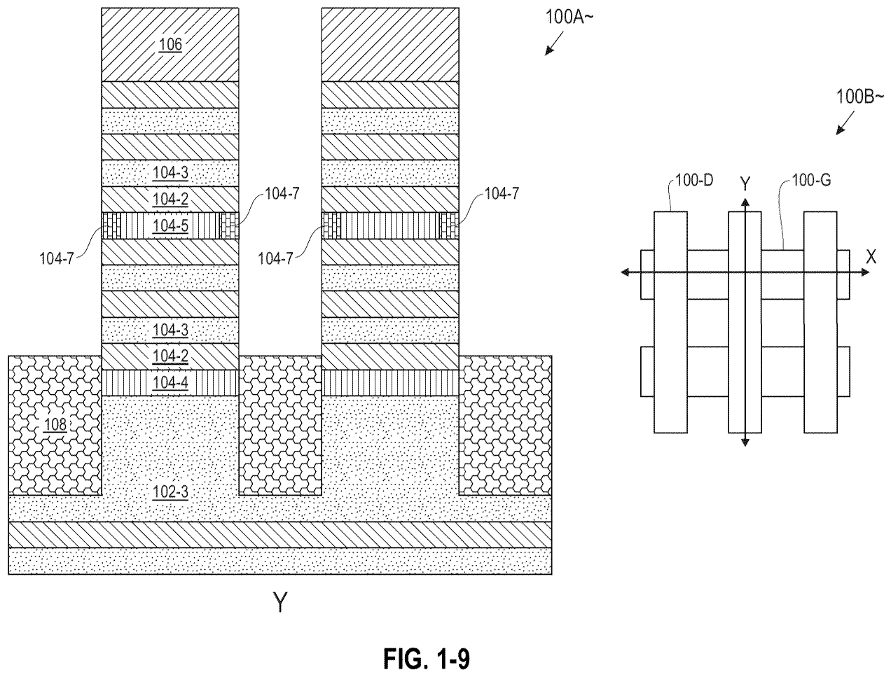

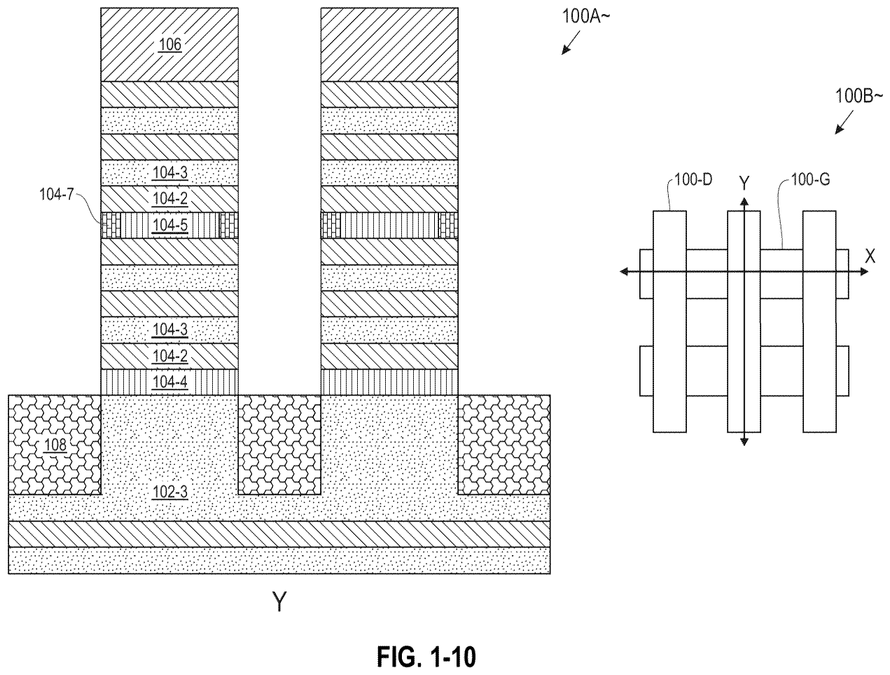

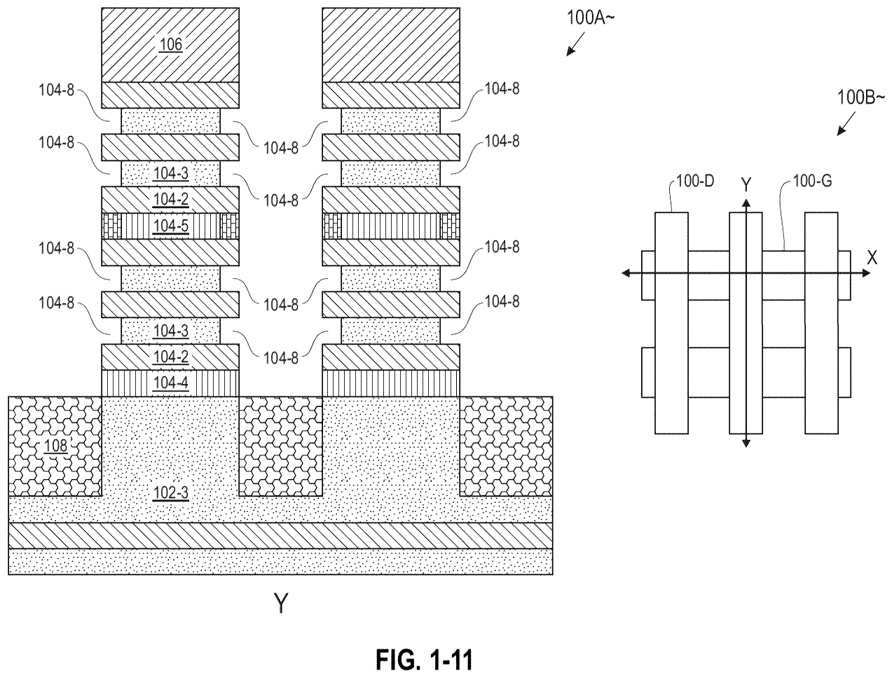

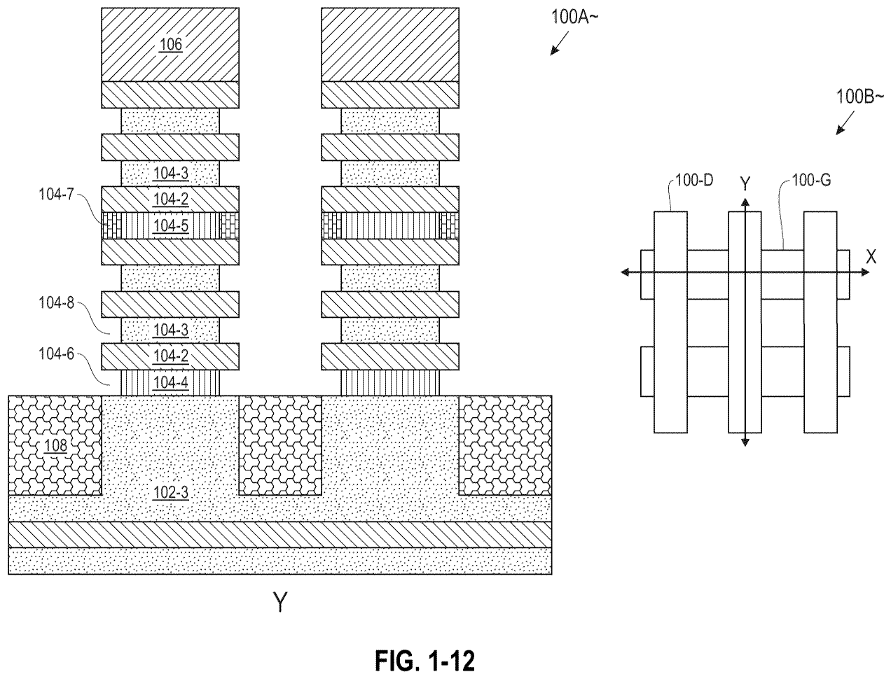

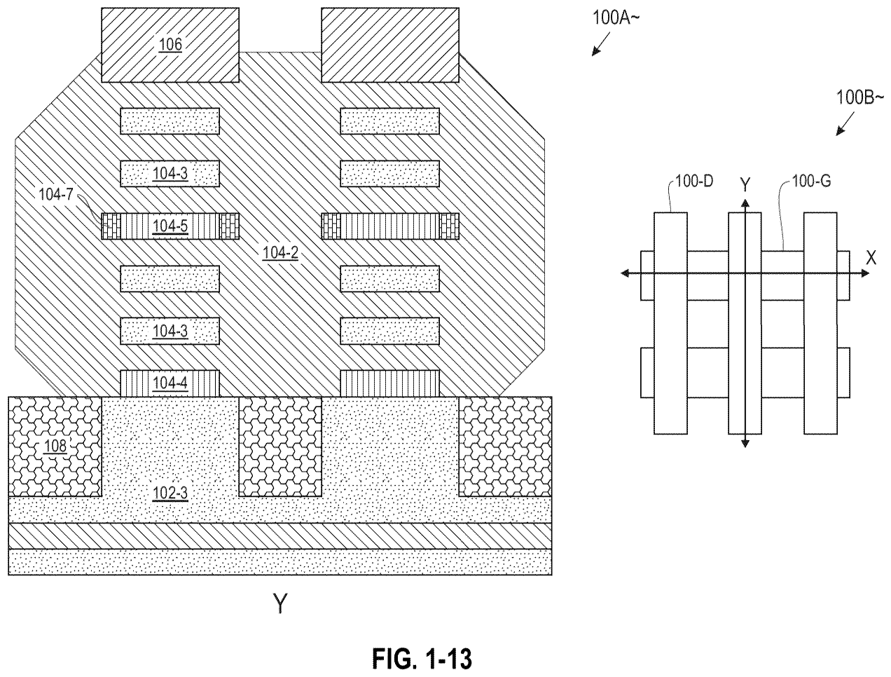

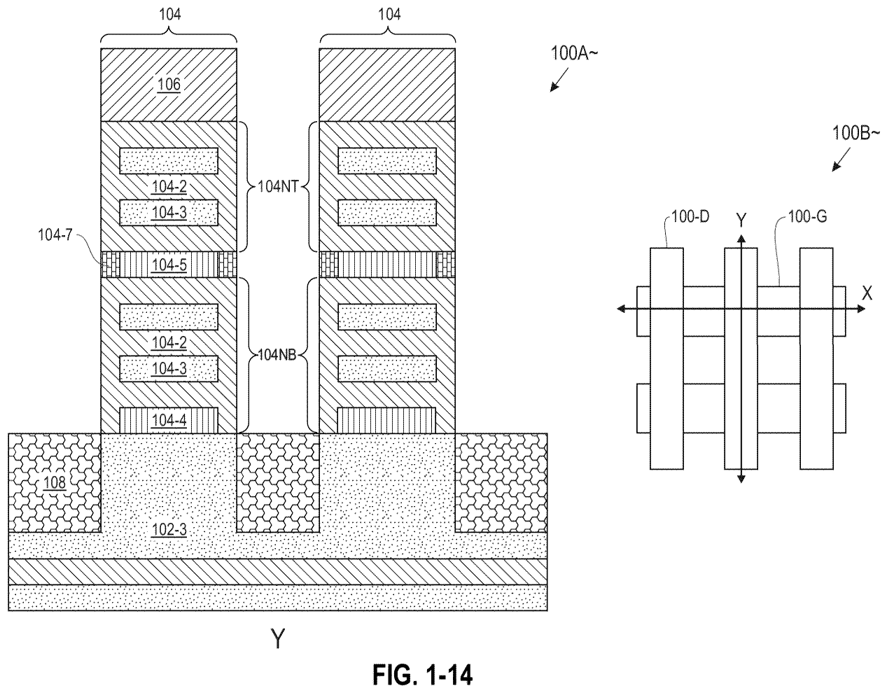

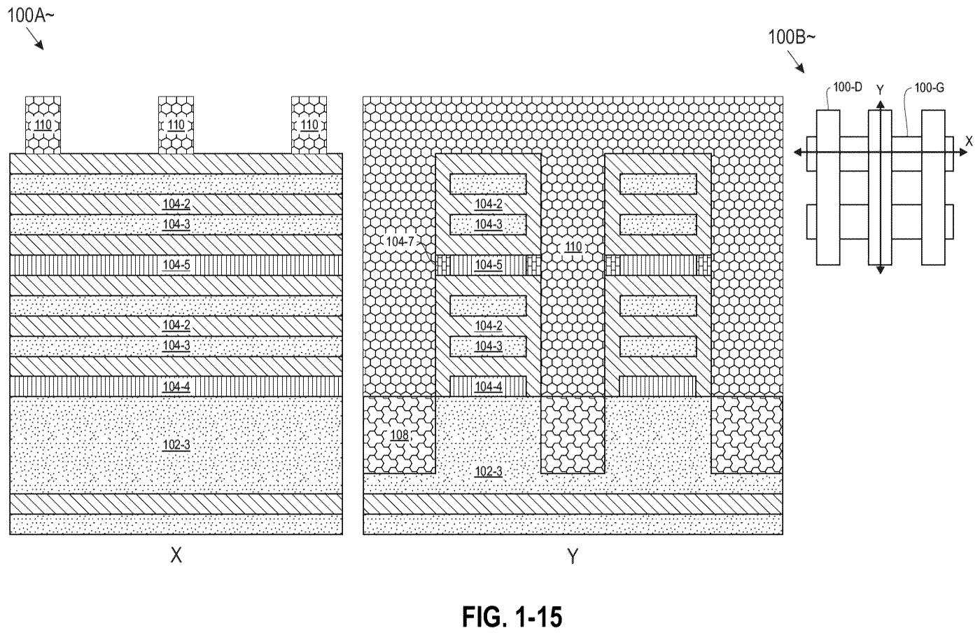

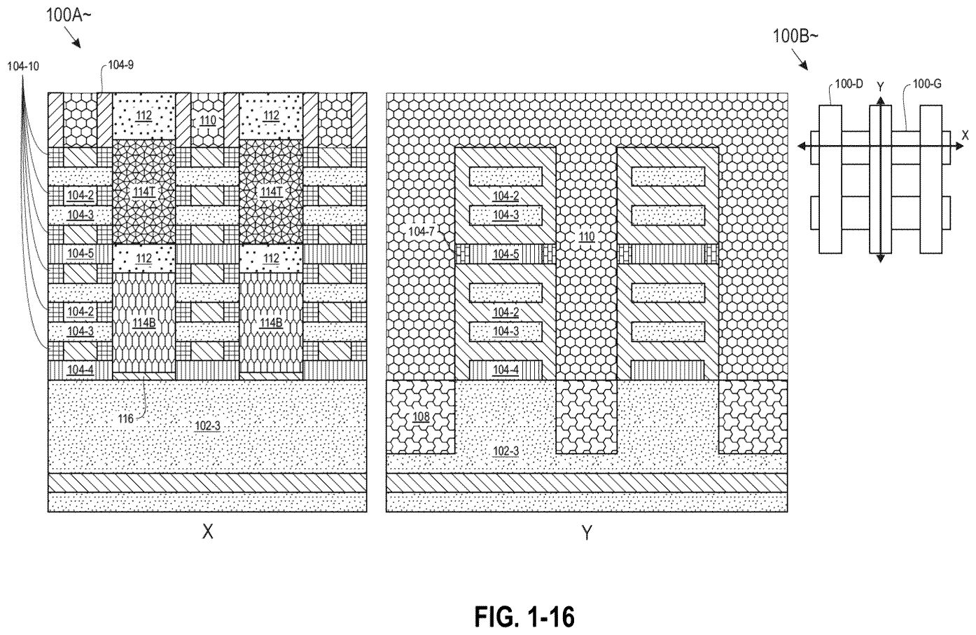

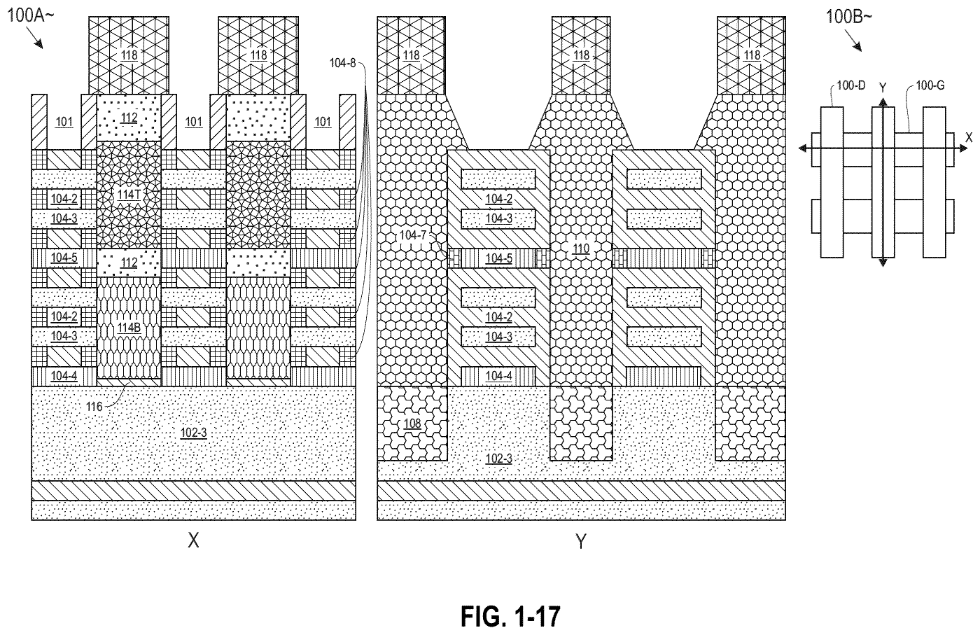

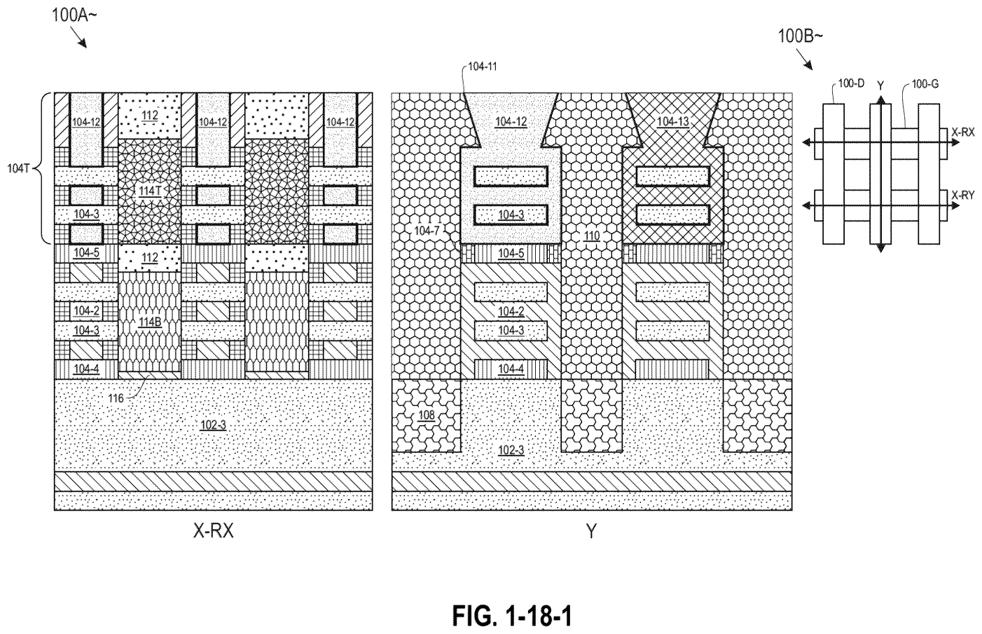

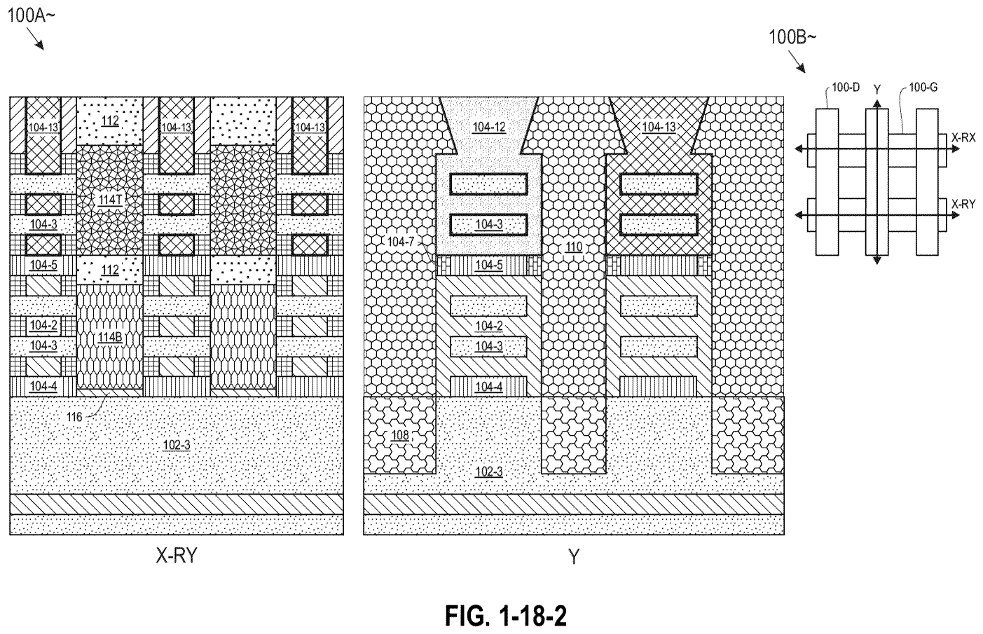

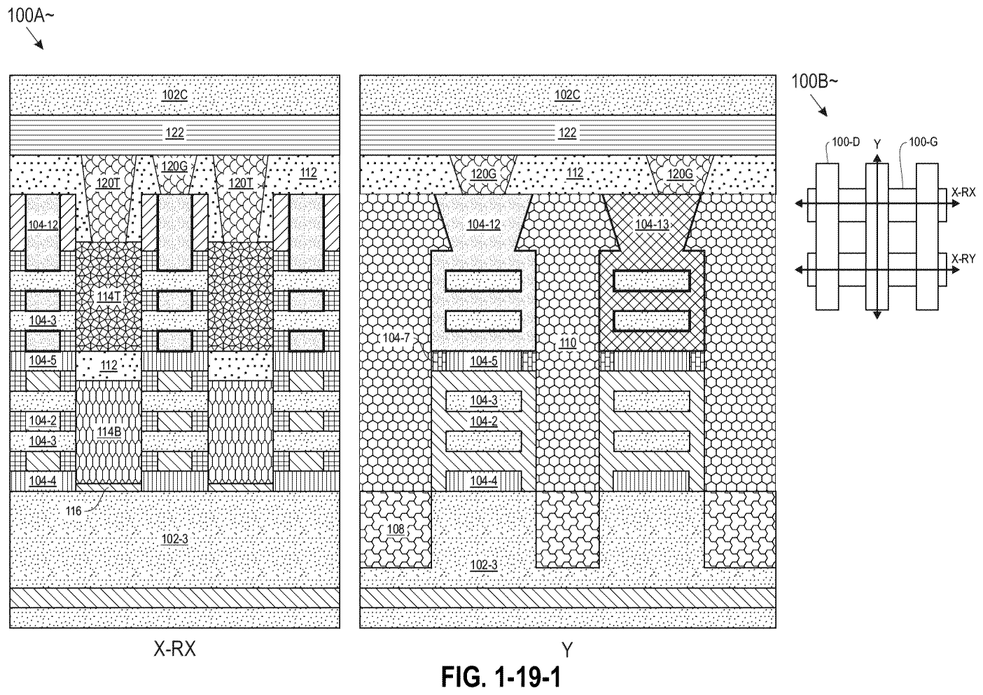

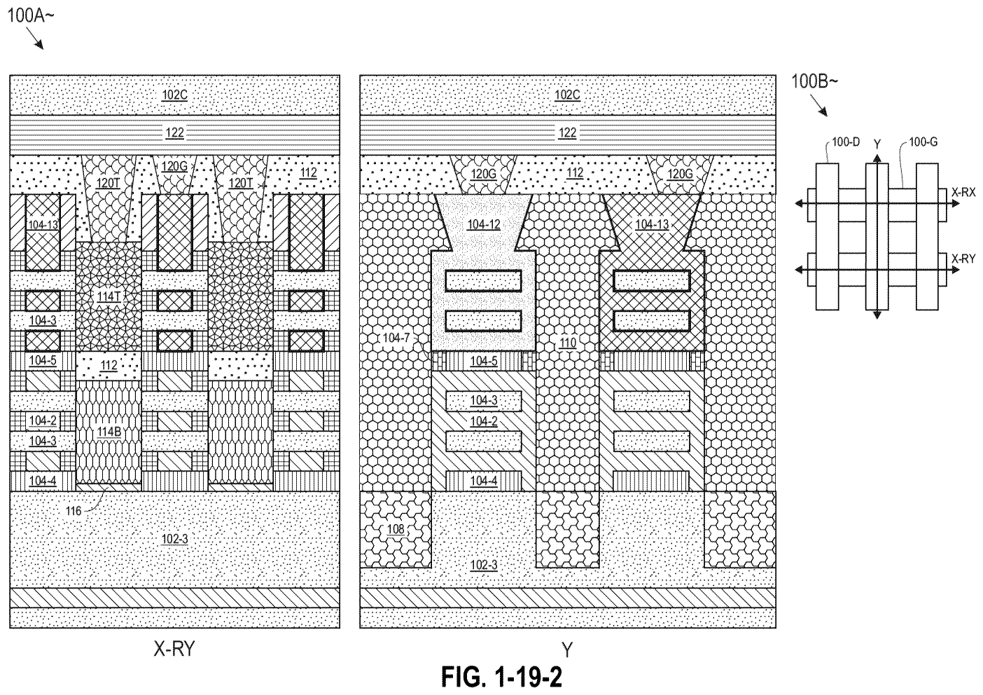

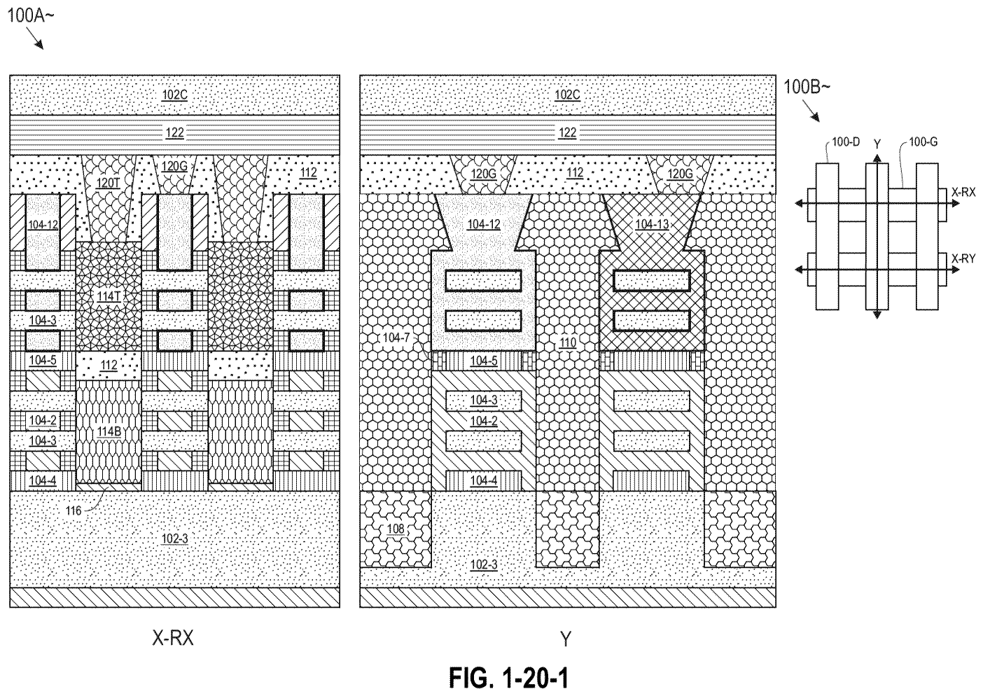

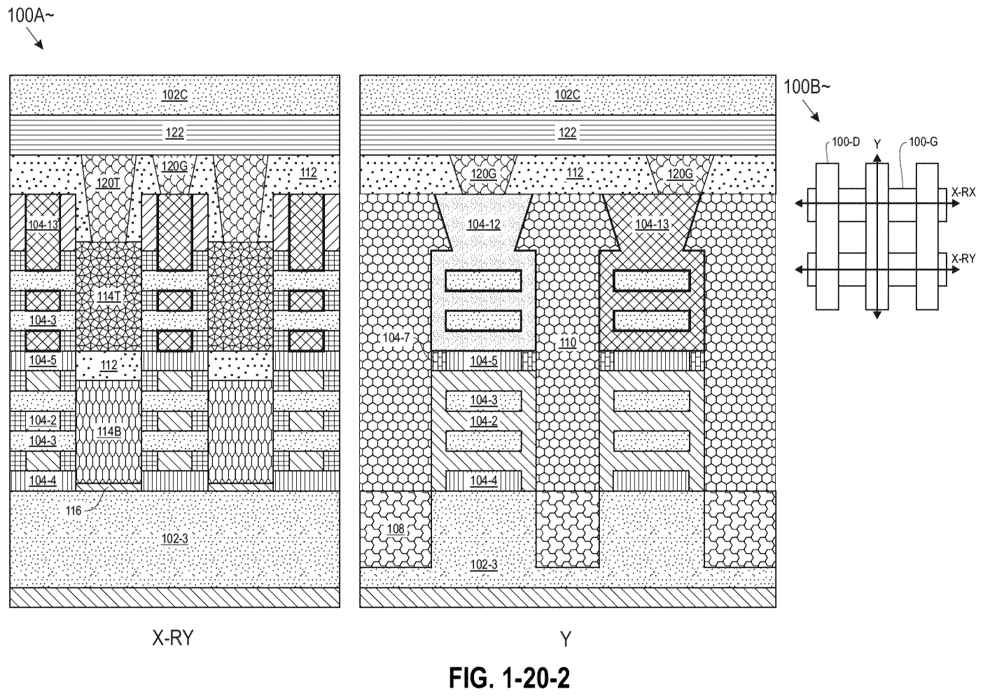

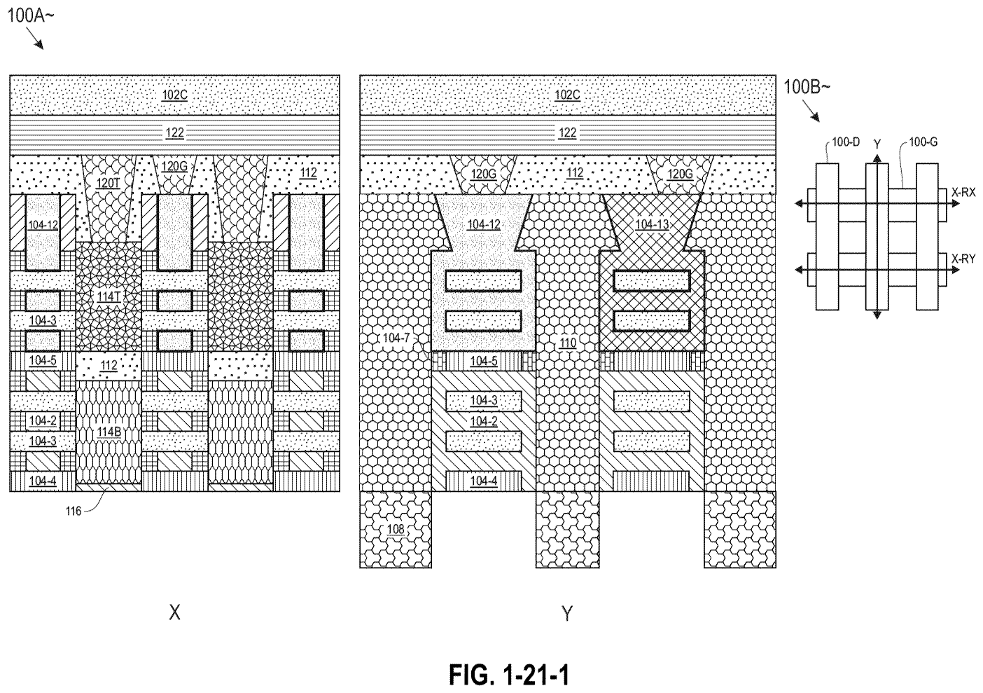

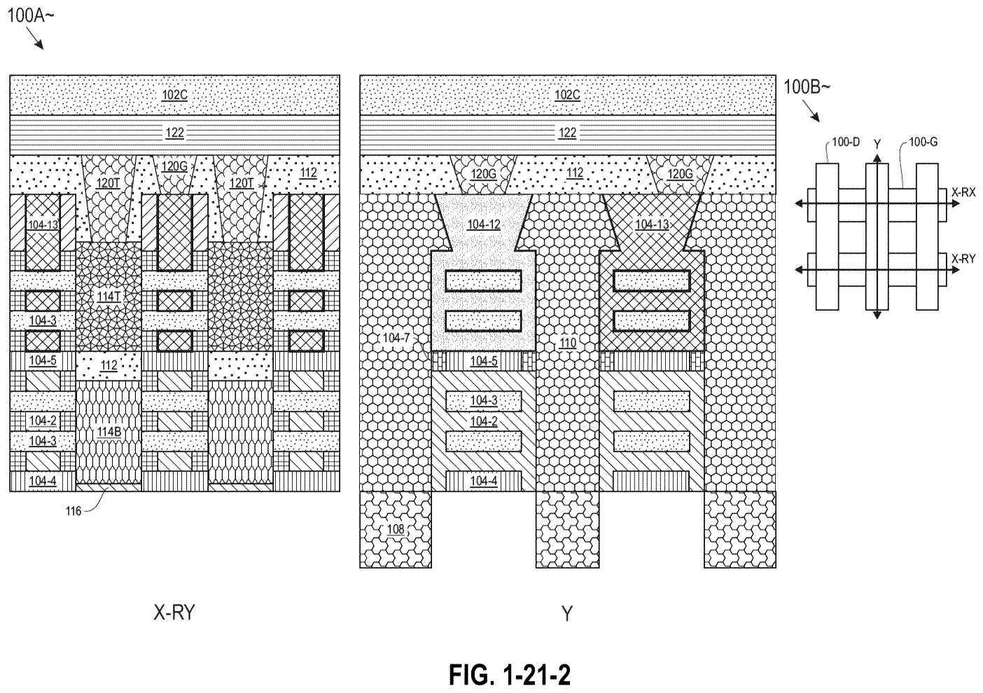

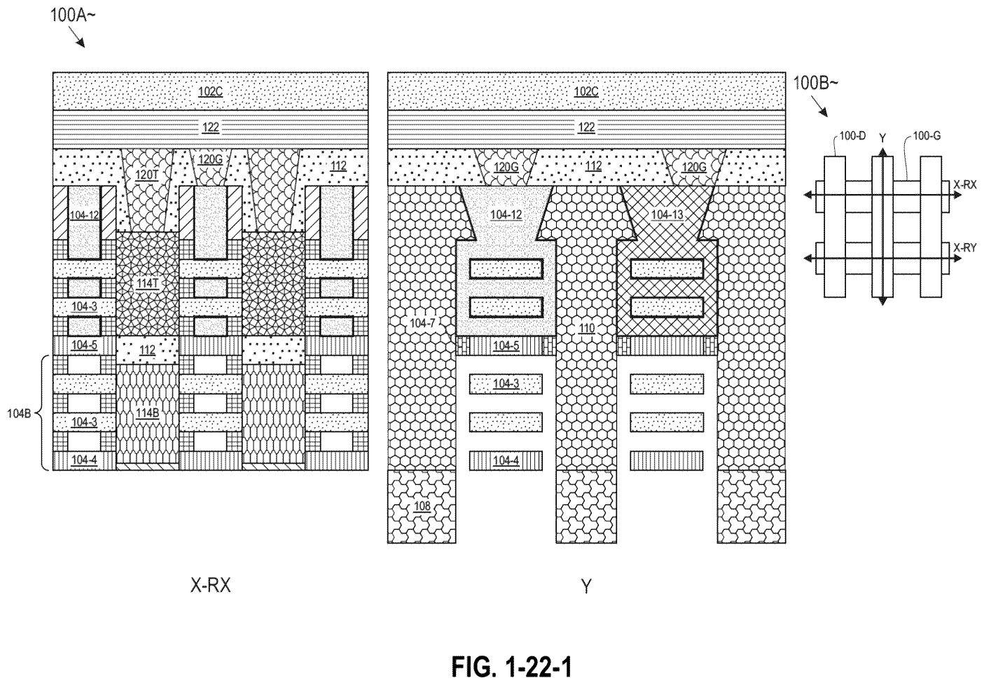

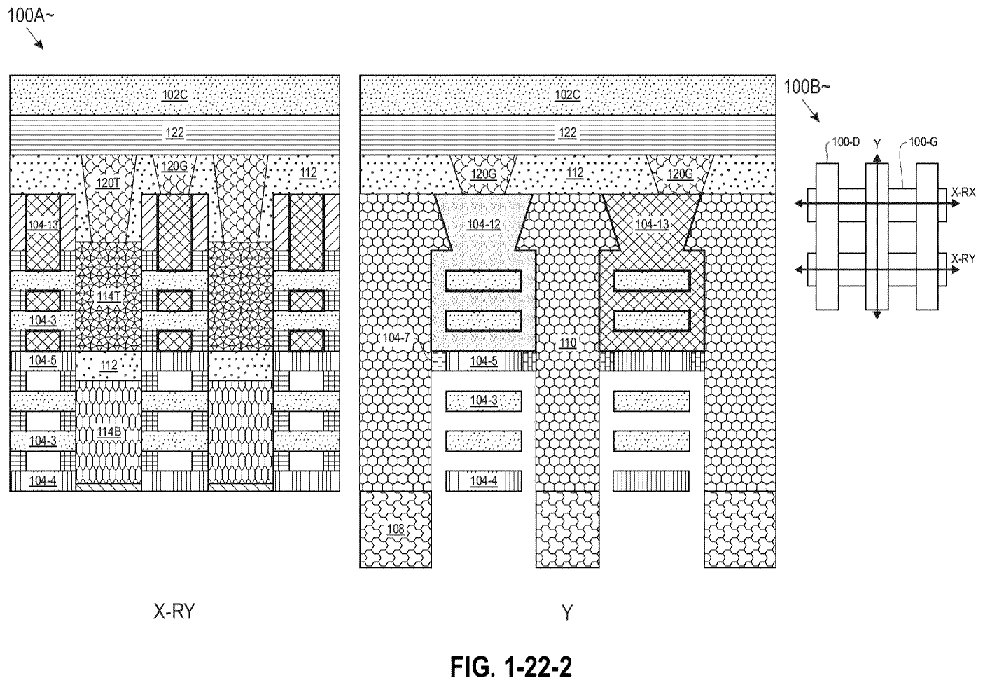

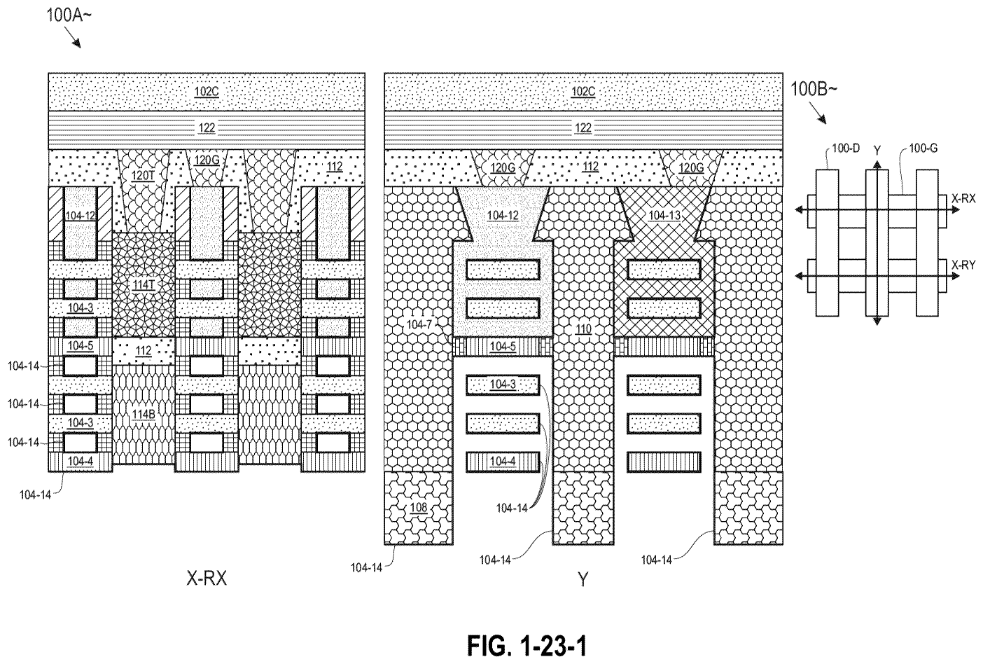

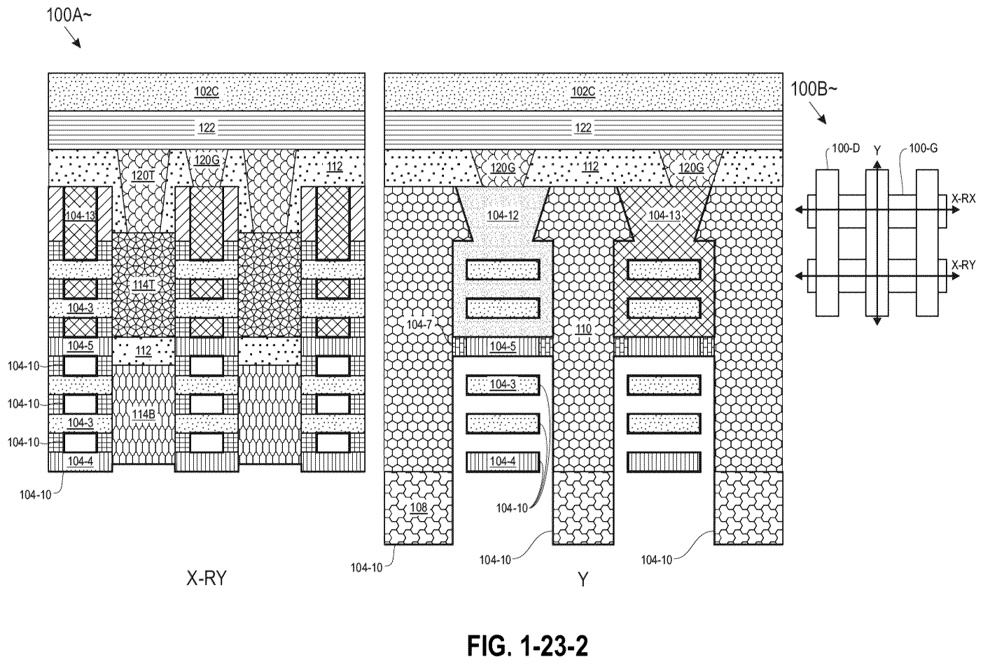

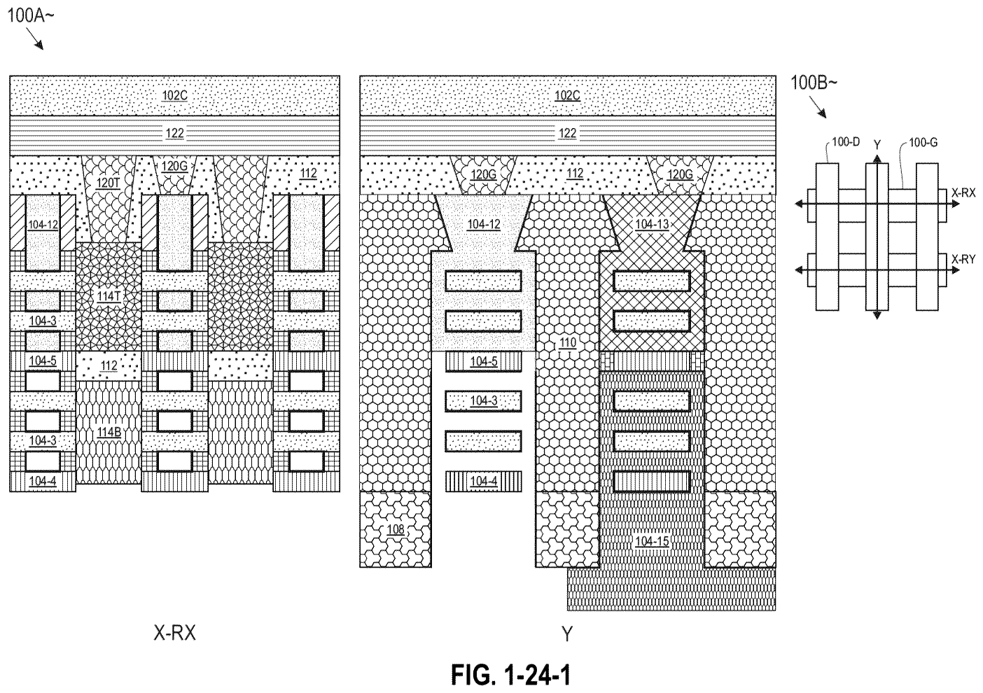

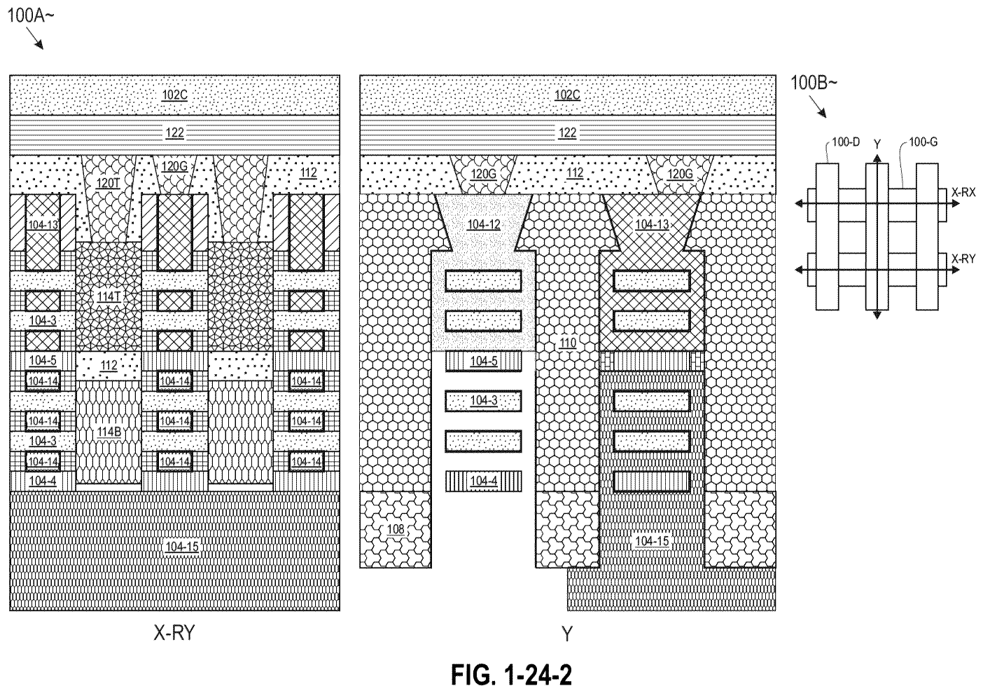

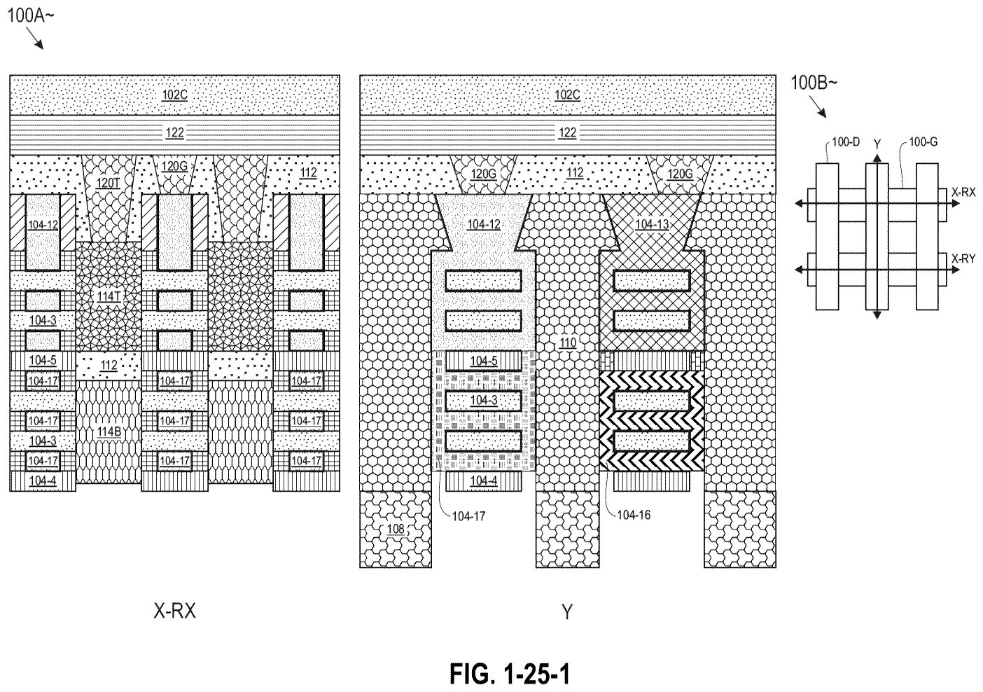

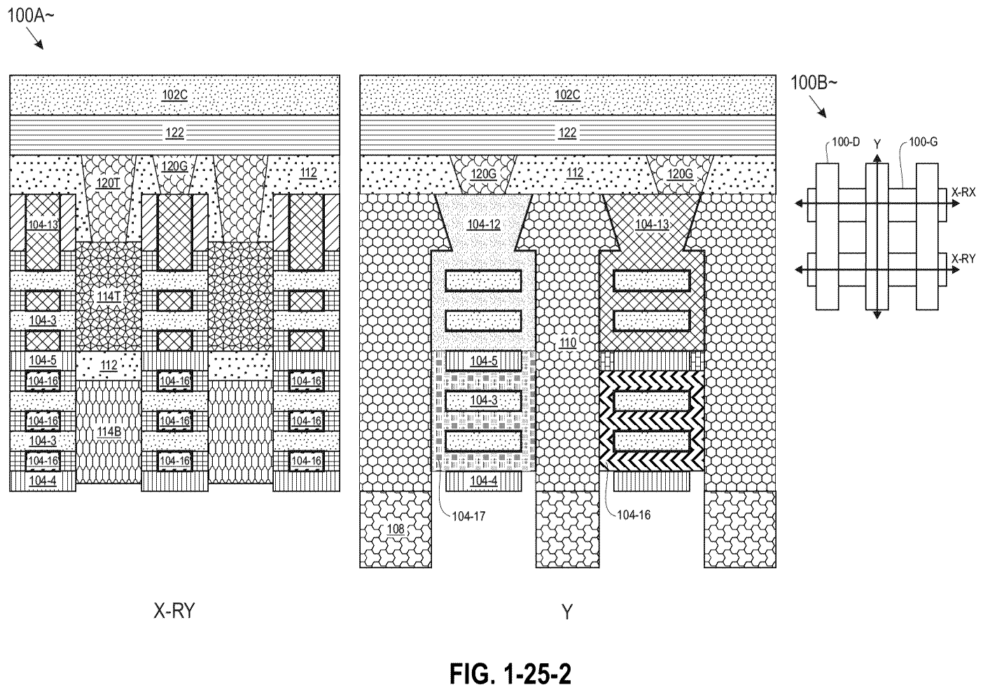

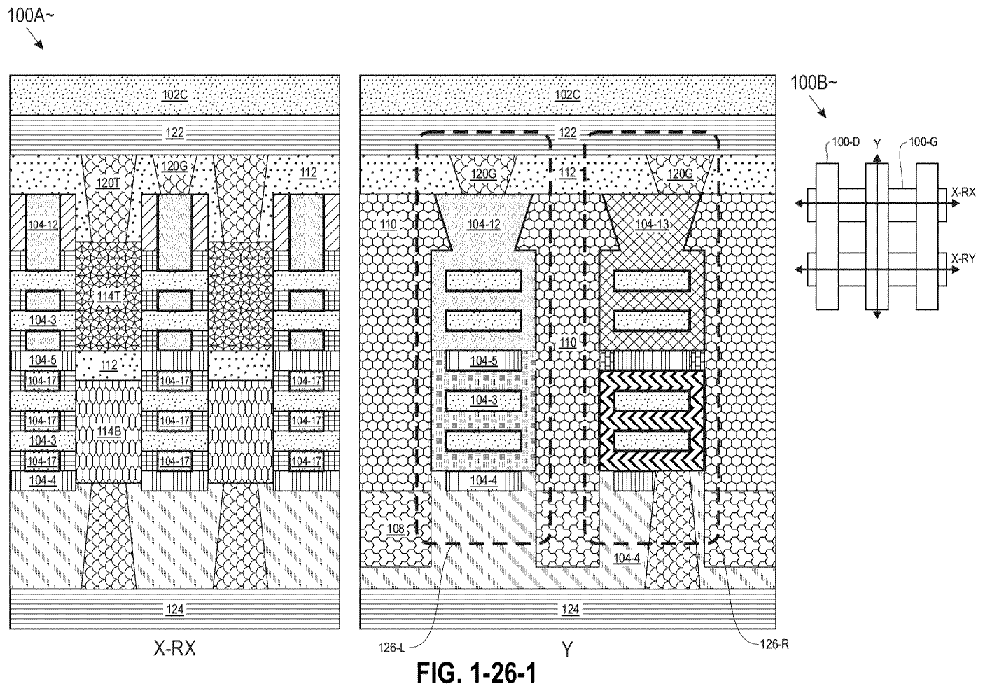

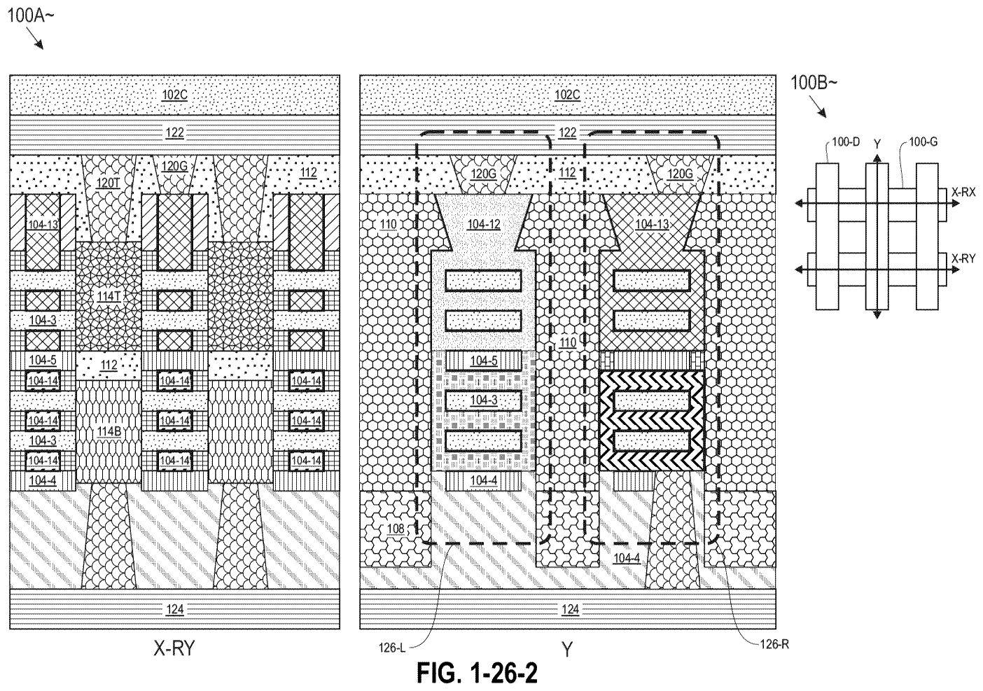

FIG. 1-1 is a cross-sectional view 100A and a top view 100B of a semiconductor structure during intermediate steps of a method for forming multiple threshold voltage stacked FET semiconductors, in accordance with some embodiments of the present disclosure. The top view 100A includes device layers 100-D and gate layers 100-G. The device layers 100-D represent the layers of the semiconductor structure for fabricating multiple threshold stacked FET devices. Further, the gate layers 100-G represent the layers for fabricating the gates to the multiple threshold stacked FETs. Additionally, the top view 100A includes cut lines X and Y. The cut line Y correlates to view Y of the cross-sectional view 100A. Further, the view Y shows a cross-section along the Y cut line. However, the cut line X is not represented in a cross-section in this figure.

The semiconductor structure 100 may result from a fabrication method wherein materials constituting each of the elements is deposited, applied, and otherwise arranged as shown. More specifically, the semiconductor structure of FIG. 1-1 may represent a starting substrate having multiple nanosheets. As shown in view Y, the semiconductor structure includes a substrate layer 102-1, etch stop layer 102-2, substrate layer 102-3, sacrificial layer 104-1, sacrificial layer 104-2, channel layers 104-3, and hardmask layer 106. The substrate layers 102-1, 102-3 (collectively referred to herein is substrate layers 102) can be a semiconductor or an insulator with an active surface semiconductor layer. The substrate layers 102 can be crystalline, semi-crystalline, microcrystalline, or amorphous. Further, the substrate layers 102 can be (except for contaminants) a single element (e.g., Si), primarily (e.g., with doping) of a single element, for example, Si or Ge, or the substrate layers 102 can include a compound, for example, aluminum oxide (Al2O3), silicon dioxide (SiO2), gallium arsenide (GaAs), silicon carbide (SiC), or SiGe. The substrate layers 102 can also have multiple material layers, for example, a semiconductor-on-insulator substrate (SeOI), a silicon-on-insulator substrate (SOI), germanium-on-insulator substrate (GeOI), or silicon-germanium-on-insulator substrate (SGOI). The substrate layers 102 can also have other layers forming the substrate layers 102, including high-k oxides and/or nitrides. In one or more embodiments, the substrate layers 102 can be a silicon wafer. In an embodiment, the substrate layers 102 can be a single crystal silicon wafer. The etch stop layer 103 may include, for example, silicon germanium, to facilitate thinning the substrate layers 102 to a desired thickness.

Additionally, the sacrificial layers 104-1, 104-2 separate the substrate layer 102-3 from the first channel layer 104-3. Further, the sacrificial layers 104-1, 104-2 may be composed of silicon germanium (SiGe), and having a particular percentage of germanium. For example, the sacrificial layers 104-1 may be 55 percent germanium (e.g., SiGe55). Further, the sacrificial layers 104-2 may be 25 percent germanium (e.g., SiGe25). Also, the hardmask layer 106 may provide protection to the top sacrificial layer 104-2, which may act as an etch stop.

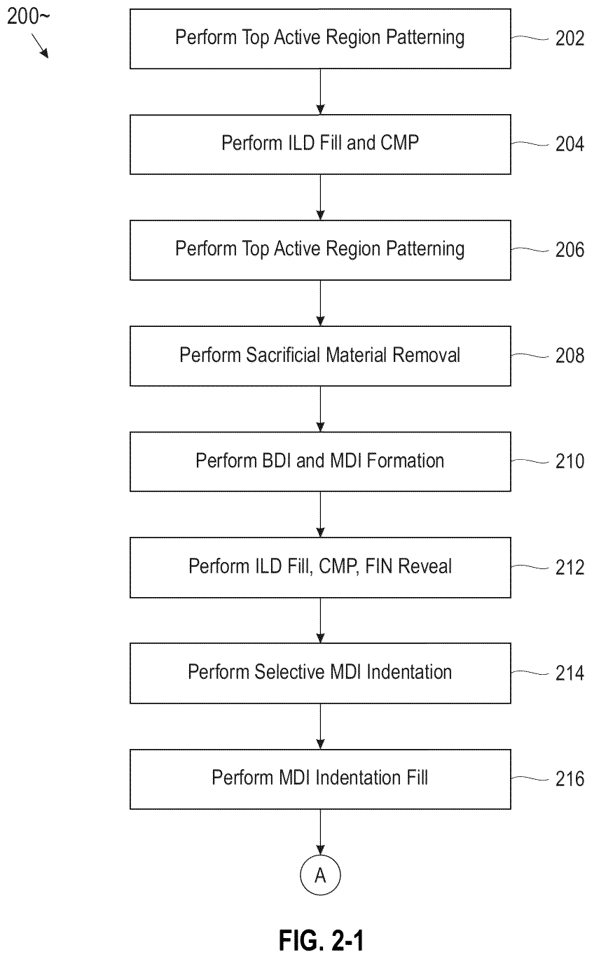

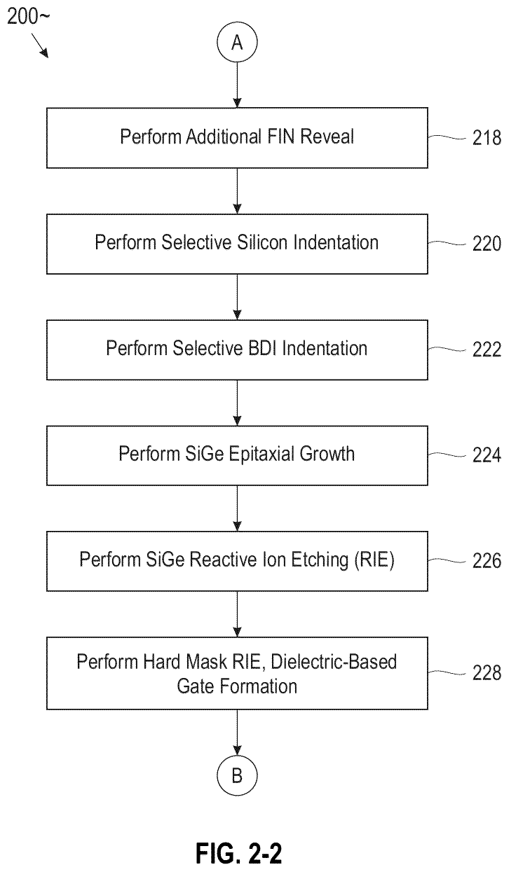

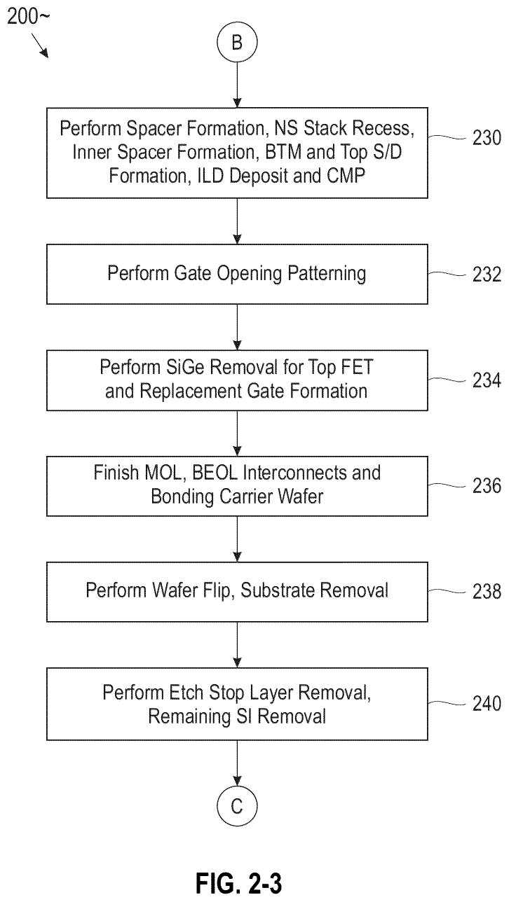

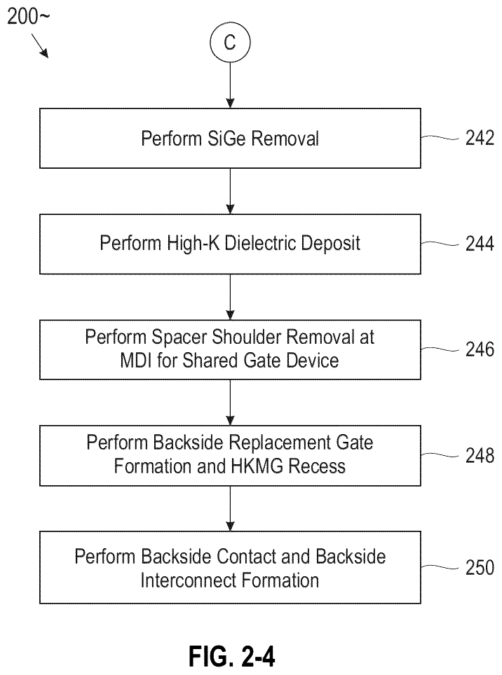

FIG. 1-2 is a cross-sectional view 100A and a top view 100B of a semiconductor structure during intermediate steps of a method for forming multiple threshold voltage stacked FET semiconductors, in accordance with some embodiments of the present disclosure. Further, the semiconductor structure of FIG. 1-2 results from performing active region (RX) patterning on the semiconductor structure of FIG. 1-1. The view Y includes the same elements described with respect to view Y of FIG. 1-1. However, the view Y shows, in comparison to FIG. 1-1, the removal of the materials on both sides of the semiconductor structure, specifically, from substrate layer 102-3, sacrificial layers 104-1, 104-2, channel layers 104-3, and hardmask layer 106 by the RX patterning.

FIG. 1-3 is a cross-sectional view 100A and a top view 100B of a semiconductor structure during intermediate steps of a method for forming multiple threshold voltage stacked FET semiconductors, in accordance with some embodiments of the present disclosure. The semiconductor structure of FIG. 1-3 results from performing an interlayer dielectric (ILD) fill and CMP on the semiconductor structure of FIG. 1-2. Performing the ILD fill can involve depositing ILD 108 in the regions where the material is removed by the RX patterning. Further, performing the CMP can involve removing portions of the ILD fill to form a planarized surface for the ILD 108 with the rest of the semiconductor structure.

FIG. 1-4 is a cross-sectional view 100A and a top view 100B of a semiconductor structure during intermediate steps of a method for forming multiple threshold voltage stacked FET semiconductors, in accordance with some embodiments of the present disclosure. The semiconductor structure of FIG. 1-4 results from performing RX patterning on the semiconductor structure of FIG. 1-3. More specifically, performing RX patterning can involve removing portions of the substrate layer 102-3, sacrificial layers 104-1, 104-2, channel layers 104-3, and hardmask layer 106, to form trench 101. Forming the trench 101 provides access to the layers substrate layer 102-3, sacrificial layers 104-1, 104-2, and channel layers 104-3.

FIG. 1-5 is a cross-sectional view 100A and a top view 100B of semiconductor structure during intermediate steps of a method for forming multiple threshold voltage stacked FET semiconductor structures, in accordance with some embodiments of the present disclosure. The semiconductor structure of FIG. 1-5 results from performing SiGe55 removal on the semiconductor structure of FIG. 1-4. As stated previously, creating trench 101 provides access to layers 104-1. Accordingly, the sacrificial layers 104-1 are removed using a chemical etch process that is selective to the sacrificial layers 104-1. This chemical etch process may form voids 104-101.

FIG. 1-6 is a cross-sectional view 100A and a top view 100B of a semiconductor structure during intermediate steps of a method for forming multiple threshold voltage stacked FET semiconductors, in accordance with some embodiments of the present disclosure. The semiconductor structure of FIG. 1-6 results from forming a bottom dielectric isolation (BDI) layer 104-4 and middle dielectric isolation (MDI) layer 104-5 on the semiconductor structure of FIG. 1-5. Forming BDI layer 104-4 and MDI layer 104-5 can involve filling the voids 104-101 with dielectric material. The BDI 104-4 and MDI 104-5 are made of the same material. More specifically, the BDI layer 104-4 and MDI layer 104-5 could be formed of a dielectric with a low dielectric constant (sometimes referred to herein as a “low-K dielectric”), such as silicon oxycarbonitride (SiOCN).

FIG. 1-7 is a cross-sectional view 100A and a top view 100B of a semiconductor structure during intermediate steps of a method for forming multiple threshold voltage stacked FET semiconductors, in accordance with some embodiments of the present disclosure. The semiconductor structure of FIG. 1-7 results from performing an ILD fill, CMP, and fin reveal on the semiconductor structure of FIG. 1-6. Performing the ILD fill can involve depositing ILD 108 in between the fins 104 of the semiconductor structure. Performing the CMP can involve removing portions of the ILD fill to form a planarized surface for the ILD 108 in the trench 101. In this way, the fins 104 of the semiconductor structure may be revealed.

FIG. 1-8 is a cross-sectional view 100A and a top view 100B of semiconductor structures during intermediate steps of a method for forming multiple threshold voltage stacked FET semiconductor structures, in accordance with some embodiments of the present disclosure. The semiconductor structure of FIG. 1-8 results from performing selective MDI indentation on the semiconductor structure of FIG. 1-8 to form divots 104-6. As stated previously, the BDI 104-4 and MDI 104-5 are made of the same material. As such, a selective etch of this material may remove the BDI 104-4 and MDI 104-5. However, in FIG. 1-8, the semiconductor structure includes ILD 108, which protects BDI 104-4 from the selective etch. Accordingly, the selective etch results in the removal of a portion of the MDI 104-5, without removing the BDI 104-4.

FIG. 1-9 is a cross-sectional view 100A and a top view 100B of a semiconductor structure during intermediate steps of a method for forming multiple threshold voltage stacked FET semiconductors, in accordance with some embodiments of the present disclosure. The semiconductor structure of FIG. 1-9 may result from filling divots on the semiconductor structure of FIG. 1-8. Filling the divots can involve filling the divots 104-6 with a dielectric that differs from the low-k dielectric of the MDI layer 104-5. Filling the divots 104-6 can form spacer shoulders 104-7. In this way, the method may form a center dielectric bar (e.g., MDI 104-5) and spacers (e.g., spacer shoulders 104-7) having a different dielectric than the MDI 104-5.

FIG. 1-10 is a cross-sectional view 100A and a top view 100B of a semiconductor structure during intermediate steps of a method for forming multiple threshold voltage stacked FET semiconductors, in accordance with some embodiments of the present disclosure. Further, the semiconductor structure of FIG. 1-10 results from performing additional fin reveal on the semiconductor structure of FIG. 1-9. Performing fin reveal can involve selective etching of portions of the ILD 108.

FIG. 1-11 is a cross-sectional view 100A and a top view 100B of a semiconductor structure during intermediate steps of a method for forming multiple threshold voltage stacked FET semiconductors, in accordance with some embodiments of the present disclosure. The semiconductor structure of FIG. 1-11 results from performing selective silicon (Si) indentation on the semiconductor structure of FIG. 1-10. Performing the selective silicon indentation can involve selectively etching portions of the channel layers 104-3 to form divots 104-8.

FIG. 1-12 is a cross-sectional view 100A and a top view 100B of a semiconductor structure during intermediate steps of a method for forming multiple threshold voltage stacked FET semiconductors, in accordance with some embodiments of the present disclosure. The semiconductor structure of FIG. 1-12 results from performing selective BDI indentation on the semiconductor structure of FIG. 1-11. Performing selective BDI indentation can involve a selective etch process that removes a portion of the BDI layer 104-4 to form divots 104-6.

FIG. 1-13 is a cross-sectional view 100A and a top view 100B of semiconductor structure 100B during intermediate steps of a method for forming multiple threshold voltage stacked FET semiconductor structures, in accordance with some embodiments of the present disclosure. The semiconductor structure of FIG. 1-13 results from performing SiGe epitaxial growth on the semiconductor structure of FIG. 1-12. Performing SiGe epitaxial growth can involve performing a conformal deposition of the SiGe25 material on the exposed surfaces of the semiconductor structure to form sacrificial layers 104-2.

FIG. 1-14 is a cross-sectional view 100A and a top view 100B of a semiconductor structure during intermediate steps of a method for forming multiple threshold voltage stacked FET semiconductors, in accordance with some embodiments of the present disclosure. The semiconductor structure of FIG. 1-14 results from reactive ion etching (RIE) on the semiconductor structure of FIG. 1-13. Performing RIE can involve removing portions of the sacrificial layers 104-2 to re-form two fins 104. In this way, the method may form a top nanosheet stack 104NT and bottom nanosheet stack 104NB, with sacrificial gate extensions (e.g., the sacrificial layers 104-2 surrounding the channel layers 104-3), and separated by the MDI 104-5.

FIG. 1-15 is a cross-sectional view 100A and a top view 100B of a semiconductor structure during intermediate steps of a method for forming multiple threshold voltage stacked FET semiconductors, in accordance with some embodiments of the present disclosure. As shown, the top view 100A includes cross-sectional views X, Y of the semiconductor structure. Further, the semiconductor structure of FIG. 1-15 results from performing hardmask RIE and dielectric-based gate formation on the semiconductor structure of FIG. 1-14. Performing the hardmask RIE can involve using RIE to remove the hardmask layer 106. Additionally, performing the dielectric-based gate formation can involve forming dielectric-based gates 110 by depositing dielectric on the device layers 100-D followed by a gate patterning and etch process.

FIG. 1-16 is a cross-sectional view 100A and a top view 100B of semiconductor structures during intermediate steps of a method for forming multiple threshold voltage stacked FET semiconductor structures, in accordance with some embodiments of the present disclosure. The semiconductor structure of FIG. 1-16 results from performing spacer formation, nanosheet stack recess, inner spacer formation, bottom source/drain (S/D), top S/D formation, ILD deposit, and CMP on the semiconductor structure of FIG. 1-15. Performing spacer formation can involve depositing dielectric material on the dielectric-based gates 110 to form spacers 104-9. Additionally, nanosheet stack recess can involve removing portions of the sacrificial layers 104-2, channel layers 104-3, BDI layer 104-4, and MDI layer 104-5 to form trenches (not shown) between the spacers 104-9 of the dielectric-based gates 110. Further, inner spacer formation can involve selective etching of the sacrificial layers 104-2 to form divots (not shown) on the sacrificial layers 104-2. Additionally, inner spacer formation can involve depositing dielectric material in the divots to form inner spacers 104-10. Further, forming bottom and top S/D formation can involve epitaxial growth to form bottom S/D 114B, top S/D 114T, and a relatively thin SiGe epitaxial layer 116. Additionally, performing ILD deposit can involve depositing ILD on top of the bottom S/D 114B and top S/D 114T to form ILD layers 112. Further, performing CMP can involve forming a planarized surface for the top ILD layer 112 with the rest of the semiconductor structure.

FIG. 1-17 is a cross-sectional view 100A and a top view 100B of a semiconductor structure during intermediate steps of a method for forming multiple threshold voltage stacked FET semiconductors, in accordance with some embodiments of the present disclosure. The semiconductor structure of FIG. 1-17 may result from performing gate opening patterning on the semiconductor structure of FIG. 1-16. Performing gate opening patterning can involve depositing an organic planarization layer 118 on top of the semiconductor structure. Additionally, performing gate opening patterning can involve etching the dielectric gate material 110 to form trenches 101.

In the following figures, the top view 100A includes X-RX and X-RY cut lines. Accordingly, the views of each intermediate step is shown in two figures, a -1 and a -2 figure. The -1 figure includes cross-section views X-RX and Y views. Further, the -2 figure includes cross-section views X-RY and Y views. The Y views are repeated in each of these figures for clarity.

FIG. 1-18-1 is a cross-sectional view 100A and a top view 100B of a semiconductor structure during intermediate steps of a method for forming multiple threshold voltage stacked FET semiconductors, in accordance with some embodiments of the present disclosure. The semiconductor structure of FIG. 1-18-1 may result from performing SiGe removal for the top FET, and forming a replacement gate on the semiconductor structure of FIG. 1-17. As shown, the X-RX view represents a cross-section view of the left fin of view Y. Performing SiGe removal on the top FET can involve removing the sacrificial layers 104-2 of the top device 104T of the semiconductor structure. Additionally, forming replacement gates can involve depositing a high-k dielectric material to form gate liners 104-11. Further forming replacement gates can involve depositing metal gates having a first work function metal to form replacement gates 104-12, and depositing a second work function metal (different from the first work function metal) to form replacement gates 104-13. In this way, some embodiments of the present disclosure can the provide multiple voltage thresholds by providing different work function metals, each with its own voltage threshold. Additionally, in this way, the method may provide a relatively straightforward work function metal patterning, without undercut between top devices, nor into bottom devices. Further, in this way, the method may form top gate stacks with multiple voltage thresholds by removing sacrificial layers 104-2 (including sacrificial gate extensions) from the top of the stack.

FIG. 1-18-2 is a cross-sectional view 100A and a top view 100B of a semiconductor structure during intermediate steps of a method for forming multiple threshold voltage stacked FET semiconductors, in accordance with some embodiments of the present disclosure. The semiconductor structure of FIG. 1-18-2 may result from SiGe removal for the top FET and forming a replacement gate on the semiconductor structure of FIG. 1-17. As shown, the X-RY view represents the right fin of view Y.

FIG. 1-19-1 is a cross-sectional view 100A and a top view 100B of a semiconductor structure during intermediate steps of a method for forming multiple threshold voltage stacked FET semiconductors, in accordance with some embodiments of the present disclosure. The semiconductor structure of FIG. 1-19-1 may result from forming the middle of line (MOL) interconnect, forming the back end of line (BEOL) interconnect 122, and bonding a carrier wafer 102C on the semiconductor structure of FIG. 1-18-1. Forming the MOL interconnect can involve depositing ILD material on the semiconductor structure, and contact metallization. The contact metallization can involve depositing metallic material to form top contacts 120T and gate contacts 120G. Forming the BEOL interconnect 122 is beyond the scope of this disclosure and not further discussed. The contact metallization can involve etching a trench through ILD 112 and filling the trench with contact metal to form the top contacts 120T and gate contacts 120G. Bonding the carrier wafer 102C can involve bonding the carrier wafer 102C to the BEOL 122. The carrier wafer 102C may be similar to the substrate layers 102.

FIG. 1-19-2 is a cross-sectional view 100A and a top view 100B of a semiconductor structure during intermediate steps of a method for forming multiple threshold voltage stacked FET semiconductors, in accordance with some embodiments of the present disclosure. The semiconductor structure of FIG. 1-19-2 may result from forming the MOL interconnect, forming the BEOL interconnect 122, and bonding the carrier wafer 1202C on the semiconductor structure of FIG. 1-18-2. As shown, the X-RY view represents the right fin of view Y.

FIG. 1-20-1 is a cross-sectional view 100A and a top view 100B of a semiconductor structure during intermediate steps of a method for forming multiple threshold voltage stacked FET semiconductors, in accordance with some embodiments of the present disclosure. The semiconductor structure of FIG. 1-20-1 may result from a wafer flip and substrate removal on the semiconductor structure of FIG. 1-19-1. Performing the wafer flip can involve reversing the vertical orientation of the semiconductor device being fabricated. However, for the sake of clarity, the disposition of the semiconductor structure remains the same in FIG. 1-20-1 as in FIG. 1-19-1. Additionally, the substrate removal can involve removing the substrate layer 102-1.

FIG. 1-20-2 is a cross-sectional view 100A and a top view 100B of a semiconductor structure during intermediate steps of a method for forming multiple threshold voltage stacked FET semiconductors, in accordance with some embodiments of the present disclosure. The semiconductor structure of FIG. 1-20-2 may result from the wafer flip and substrate 102-1 removal on the semiconductor structure of FIG. 1-19-2. As shown, the X-RY view represents the right fin of view Y.

FIG. 1-21-1 is a cross-sectional view 100A and a top view 100B of a semiconductor structure during intermediate steps of a method for forming multiple threshold voltage stacked FET semiconductors, in accordance with some embodiments of the present disclosure. The semiconductor structure of FIG. 1-21-1 may result from removing the etch stop layer 102-2 and the substrate layer 102-3 of the semiconductor structure of FIG. 1-20-1. Removing the etch stop layer 102-2 and substrate layer 102-3 can involve a chemical and/or mechanical removal of the materials of these layers.

FIG. 1-21-2 is a cross-sectional view 100A and a top view 100B of a semiconductor structure during intermediate steps of a method for forming multiple threshold voltage stacked FET semiconductors, in accordance with some embodiments of the present disclosure. The semiconductor structure of FIG. 1-21-2 may result from removing the etch stop layer 102-2 and the substrate layer 102-3 of the semiconductor structure of FIG. 1-20-2. As shown, the X-RY view represents the right fin of view Y.

FIG. 1-22-1 is a cross-sectional view 100A and a top view 100B of a semiconductor structure during intermediate steps of a method for forming multiple threshold voltage stacked FET semiconductors, in accordance with some embodiments of the present disclosure. The semiconductor structure of FIG. 1-22-1 may result from removing the sacrificial layers 104-2 of the semiconductor structure of FIG. 1-21-1. Removing the sacrificial layers 104-2 can involve a selective etch of the material of the sacrificial layers 104-2.

FIG. 1-22-2 is a cross-sectional view 100A and a top view 100B of a semiconductor structure during intermediate steps of a method for forming multiple threshold voltage stacked FET semiconductors, in accordance with some embodiments of the present disclosure. The semiconductor structure of FIG. 1-22-2 may result from removing the sacrificial layers 104-2 of the semiconductor structure of FIG. 1-21-2. As shown, the X-RY view represents the right fin of view Y.

FIG. 1-23-1 is a cross-sectional view 100A and a top view 100B of a semiconductor structure during intermediate steps of a method for forming multiple threshold voltage stacked FET semiconductors, in accordance with some embodiments of the present disclosure. The semiconductor structure of FIG. 1-23-1 may result from a high-k dielectric deposit on the semiconductor structure of FIG. 1-22-1. Performing the high-k electric deposit can form the dielectric liners 104-14.

FIG. 1-23-2 is a cross-sectional view 100A and a top view 100B of a semiconductor structure during intermediate steps of a method for forming multiple threshold voltage stacked FET semiconductors, in accordance with some embodiments of the present disclosure. The semiconductor structure of FIG. 1-23-2 may result from removing the sacrificial layers 104-2 of the semiconductor structure of FIG. 1-22-2. As shown, the X-RY view represents the right fin of view Y.

FIG. 1-24-1 is a cross-sectional view 100A and a top view 100B of a semiconductor structure during intermediate steps of a method for forming multiple threshold voltage stacked FET semiconductors, in accordance with some embodiments of the present disclosure. The semiconductor structure of FIG. 1-24-1 may result from removing the spacer shoulders 104-7 at MDI layer 104-5 on the semiconductor structure of FIG. 1-23-1. Removing the spacer shoulders 104-7 can involve a selective etching of the material of the spacer shoulders 104-7 on the left fin 104 of the semiconductor structure. In this method, the left fin 104 can represent a fabrication of a shared gate device. As the spacer shoulders 104-7 of the right fin is composed of the same material as the spacer shoulders 104-7 of the left fin, a selective etch of this material may remove the spacer shoulders 104-7 of both fins. Accordingly, before the selective etching, the method may include depositing an OPL 104-15 on the bottom of the right fin 104. In this way, the OPL 104-15 protects the spacer shoulders 104-7 of the right fin 104 from the selective etch. Further, the selective etch may be a directional etch. Accordingly, the selective etch may additionally remove the exposed dielectric liner 104-14 from the bottom of the BDI 104-4 in the left fin, shown in the Y view.

FIG. 1-24-2 is a cross-sectional view 100A and a top view 100B of a semiconductor structure during intermediate steps of a method for forming multiple threshold voltage stacked FET semiconductors, in accordance with some embodiments of the present disclosure. The semiconductor structure of FIG. 1-24-2 may result from removing the spacer shoulders 104-7 at MDI layer 104-5 on the semiconductor structure of FIG. 1-23-2. As shown, the X-RY view represents the right fin of view Y.

FIG. 1-25-1 is a cross-sectional view 100A and a top view 100B of a semiconductor structure during intermediate steps of a method for forming multiple threshold voltage stacked FET semiconductors, in accordance with some embodiments of the present disclosure. The semiconductor structure of FIG. 1-25-1 may result from forming backside replacement gates, and performing an HKMG recession on the semiconductor structure of FIG. 1-24-1. Forming the backside replacement gate can involve removing the OPL 104-15, depositing work function metal 104-16 in the right fin 104, and depositing work function metal 104-17 (different from work function metal 104-16) in the left fin 104. Performing the HKMG recession can involve removing the materials of the exposed dielectric liners 104-14. In this way, the method may form a bottom gate stack with multiple voltage thresholds. As shown, the gate 104-12 is a shared gate device where the WFM of the top gate is connected to the WFM of the bottom gate (e.g., gate 104-17 through removing and replacing the spacer 104-7 (described with respect to FIGS. 24-1, 25-1. In contrast, the gates 104-13 and 104-16 are independent gate devices, and their respective WFM's are separated by spacer shoulders 104-7 on either side of the MDI 104-5. However, the shared gate and independent gate devices may all have different threshold voltages.

FIG. 1-25-2 is a cross-sectional view 100A and a top view 100B of a semiconductor structure during intermediate steps of a method for forming multiple threshold voltage stacked FET semiconductors, in accordance with some embodiments of the present disclosure. The semiconductor structure of FIG. 1-25-2 may result from forming backside replacement gates, and performing an HKMG recession on the semiconductor structure of FIG. 1-24-2. As shown, the X-RY view represents the right fin of view Y.

FIG. 1-26-1 is a cross-sectional view 100A and a top view 100B of a semiconductor structure during intermediate steps of a method for forming multiple threshold voltage stacked FET semiconductors, in accordance with some embodiments of the present disclosure. The semiconductor structure of FIG. 1-26-1 may result from forming backside contacts and the backside interconnect on the semiconductor structure of FIG. 1-25-1. Forming backside contacts 120B can be similar to the process of forming contacts 120T, 120G. However, forming the backside interconnect 124 is beyond the scope of this disclosure and not further discussed. As shown, the semiconductor structure includes two stacked FET devices the left stacked FET 126-L and the right stacked FET 126-R. The left stacked FET 126-L includes connected gates, and right stacked FET 126-R have two gates with independent gate control by separate frontside and backside gate contacts.

FIG. 1-26-2 is a cross-sectional view 100A and a top view 100B of a semiconductor structure during intermediate steps of a method for forming multiple threshold voltage stacked FET semiconductors, in accordance with some embodiments of the present disclosure. The semiconductor structure of FIG. 1-26-2 may result from forming backside contacts 120B and backside interconnect 124 on the semiconductor structure of FIG. 1-25-2. As shown, the X-RY view represents the right fin of view Y.

FIGS. 2-1 through 2-4 represent a process flow chart of a method 200 for forming multiple threshold voltage stacked FET semiconductors, in accordance with some embodiments of the present disclosure. The method 200 may be similar to the method represented in FIGS. 1-1 through 1-17, and FIGS. 1-18-1, 1-18-2 through FIGS. 1-26-1, 1-26-2, to produce a semiconductor structure.

At operation 202, a fabrication tool can perform top active region patterning, described with respect to FIG. 1-2. As stated previously, performing top active region patterning can involve removal of the materials on both sides of the semiconductor structure, specifically, from substrate layer 102-3, sacrificial layers 104-1, 104-2, channel layers 104-3, and hardmask layer 106.

At operation 204, a fabrication tool may perform ILD fill and CMP, described with respect to FIG. 1-3. As stated previously, performing ILD fill and CMP can involve performing the ILD fill involves depositing ILD 108 in the regions where the material is removed by the RX patterning. Further, performing the CMP involves removing portions of the ILD fill to form a planarized surface for the ILD 108 with the rest of the semiconductor structure.

At operation 206, a fabrication tool can perform top active region patterning, described with respect to FIG. 1-4. As stated previously, performing top active region patterning can involve removing portions of the substrate layer 102-3, sacrificial layers 104-1, 104-2, channel layers 104-3, and hardmask layer 106, to form trench 101. Forming the trench 101 provides access to the layers substrate layer 102-3, sacrificial layers 104-1, 104-2, and channel layers 104-3.

At operation 208, a fabrication tool can perform sacrificial material removal, described with respect to FIG. 1-5. As stated previously, performing sacrificial material removal can involve removing the sacrificial layers 104-1 using a chemical etch process that is selective to the sacrificial layers 104-1. This chemical etch process may form voids 104-101.

At operation 210, a fabrication tool can perform BDI and MDI formation, described with respect to FIG. 1-6. As stated previously, BDI and MDI formation involves forming the BDI layer 104-4 and MDI layer 104-5. More specifically, forming the BDI layer 104-4 and MDI layer 104-5 can involve filling the voids 104-101 with dielectric material. The BDI 104-4 and MDI 104-5 are made of the same material. More specifically, the BDI layer 104-4 and MDI layer 104-5 could be formed of a dielectric with a low dielectric constant (sometimes referred to herein as a “low-K dielectric”), such as silicon oxycarbonitride (SiOCN).

At operation 212, a fabrication tool can perform ILD fill, CMP, and fin reveal, described with respect to FIG. 1-7. As stated previously, performing ILD fill, CMP, and fin reveal can involve depositing ILD 108 in between the fins 104 of the semiconductor structure. Performing the CMP can involve removing portions of the ILD fill to form a planarized surface for the ILD 108 in the trench 101. In this way, the fins 104 of the semiconductor structure may be revealed.

At operation 214, a fabrication tool can perform selective MDI indentation, described with respect to FIG. 1-8. As stated previously, performing selective MDI indentation can involve forming divots 104-6 with a selective etch of the material of MDI 104-5, with the same material of the BDI 104-4 protected from the selective etch by the ILD 108. Accordingly, the selective etch results in the removal of a portion of the MDI 104-5, without removing the BDI 104-4.

At operation 216, a fabrication tool can perform MDI indentation fill, described with respect to FIG. 1-9. As stated previously, performing MDI indentation fill can involve filling divots 104-6 on the semiconductor structure of FIG. 1-8. The fabrication tool may fill the divots 104-6 with a dielectric that differs from the low-k dielectric of the MDI layer 104-5. In this way, filling the divots 104-6 can form spacer shoulders 104-7.

The process flow chart of the method 200 in FIG. 2-1 shows control flowing from operation 216 to a placeholder “A.” Accordingly, the method 200 continues in FIG. 2-2. In FIG. 2-2, the method 200 shows control flowing from the placeholder “A to operation 218.

At operation 218, a fabrication tool may perform an additional fin reveal, described with respect to FIG. 1-10. As stated previously, performing the additional fin reveal can involve selective etching of portions of the ILD 108.

At operation 220, a fabrication tool can perform selective silicon indentation, described with respect to FIG. 1-11. As stated previously, performing selective silicon indentation selectively etching portions of the channel layers 104-3 to form divots 104-8.

At operation 222, a fabrication tool may perform selective BDI indentation, described with respect to FIG. 1-12. As stated previously, performing selective BDI indentation can involve a selective etch process that removes a portion of the BDI layer 104-4 to form divots 104-6.

At operation 224, a fabrication tool can perform SiGe epitaxial growth, described with respect to FIG. 1-13. As stated previously, performing SiGe epitaxial growth can involve performing a conformal deposition of the SiGe55 material on the exposed surfaces of the semiconductor structure to form sacrificial layers 104-2.

At operation 226, a fabrication tool can perform SiGe RIE, described with respect to FIG. 1-14. As stated previously, performing SiGe RIE can involve removing portions of the sacrificial layers 104-2 using RIE.

At operation 228, a fabrication tool can perform hard mask RIE, and dielectric-based gate formation, described with respect to FIG. 1-15. As stated previously, performing hard mask RIE, and dielectric-based gate formation using RIE to remove the hardmask layer 106. Additionally, performing the dielectric-based gate formation can involve forming dielectric-based gates 110 by depositing dielectric on the device layers 100-D.

The process flow chart of the method 200 in FIG. 2-2 shows control flowing from operation 228 to a placeholder “B.” Accordingly, the method 200 continues in FIG. 2-3. In FIG. 2-3, the method 200 shows control flowing from the placeholder “B” to operation 230.

At operation 230, a fabrication tool can perform spacer formation, nanosheet stack recess, inner spacer formation, bottom source/drain (S/D), top S/D formation, ILD deposit, and CMP, described with respect to FIG. 1-16. As stated previously, performing spacer formation, nanosheet stack recess, inner spacer formation, bottom source/drain (S/D), top S/D formation, ILD deposit, and CMP can involve depositing dielectric material on the dielectric-based gates 110 to form spacers 104-9. Additionally, nanosheet stack recess can involve removing portions of the sacrificial layers 104-2, channel layers 104-3, BDI layer 104-4, and MDI layer 104-5 to form trenches (not shown) between the spacers 104-9 of the dielectric-based gates 110. Further, inner spacer formation can involve selective etching of the sacrificial layers 104-2 to form divots (not shown) on the sacrificial layers 104-2. Additionally, inner spacer formation can involve depositing dielectric material in the divots to form inner spacers 104-10. Further, forming bottom and top S/D formation can involve epitaxial growth to form bottom S/D 114B, top S/D 114T, and a relatively thin SiGE epitaxial layer 116. Additionally, performing ILD deposit can involve depositing ILD on top of the bottom S/D 114B and top S/D 114T to form ILD layers 112. Further, performing CMP can involve forming a planarized surface for the top ILD layer 112 with the rest of the semiconductor structure.

At operation 232, a fabrication tool can perform gate opening patterning, described with respect to FIG. 1-17. As stated previously, performing gate opening patterning can involve depositing an organic planarization layer 118 on top of the semiconductor structure. Additionally, performing gate opening patterning can involve performing gate cuts to form trenches 101.

At operation 234, a fabrication tool can perform SiGe removal for top FET and replacement gate formation, described with respect to FIGS. 1-18-1, 1-18-2. As stated previously, performing SiGe removal for top FET and replacement gate formation can involve removing the sacrificial layers 104-2 of the top device 104T of the semiconductor structure. Additionally, forming replacement gates can involve depositing a high-k dielectric material to form gate liners 104-11. Further forming replacement gates can involve depositing a first work function metal to form replacement gates 104-12, and depositing a second work function metal (different from the first work function metal) to form replacement gates 104-13. In this way, some embodiments of the present disclosure can provide a relatively straightforward work function metal patterning, without undercut between top devices, nor into bottom devices.

At operation 236, a fabrication tool can form MOL, BEOL interconnects and bonding carrier wafer, described with respect to FIGS. 1-19-1, 1-19-2. As stated previously, forming MOL, BEOL interconnects and bonding carrier wafer can involve depositing ILD material on the semiconductor structure, and contact metallization. The contact metallization can involve depositing metallic material to form top contacts 120T and gate contacts 120G. The contact metallization may involve etching a trench through ILD 112 and filling the trench with contact metal to form the top contacts 120T and gate contacts 120G. Bonding the carrier wafer 102C can involve bonding the carrier wafer 102C to the BEOL 122. The carrier wafer 102C may be similar to the substrate layers 102-1, 102-3.

At operation 238, a fabrication tool can perform wafer flip and substrate removal, described with respect to FIGS. 1-20-1, 1-20-2. As stated previously, performing wafer flip and substrate removal can involve reversing the vertical orientation of the semiconductor device being fabricated. However, for the sake of clarity, the disposition of the semiconductor structure remains the same in FIG. 1-20-1 as in FIG. 1-19-1. Additionally, the substrate removal can involve removing the substrate layer 102-1.

At operation 240, a fabrication tool can perform etch stop layer removal and remaining substrate removal, described with respect to FIGS. 1-21-1, 1-21-2. As stated previously, performing etch stop layer removal and remaining substrate removal can involve a chemical and/or mechanical removal of the materials of substrate layers 102-1, 102-3, and etch stop layer 102-2.

At operation 242, a fabrication tool can perform SiGe removal on the semiconductor structure shown in FIGS. 1-22-1, 1-22-2. As stated previously, performing SiGe removal can involve a selective etch of the material of the sacrificial layers 104-2.

At operation 244, a fabrication tool can perform high-K dielectric deposit, described with respect to FIGS. 1-23-1, 1-23-2. As stated previously, performing high-k dielectric deposit can involve removing material from the bottom contact metals 122-1 to form bottom contacts, such as the bottom contacts 122. Additionally, performing high-K dielectric deposit involve depositing a high-K dielectric to form the dielectric liners 104-14.

At operation 246, a fabrication tool can perform spacer shoulder removal at MDI for the shared gate device, described with respect to FIGS. 1-24-1, 1-24-2. As stated previously, spacer shoulder removal at MDI for the shared gate device can involve a selective etching of the material of the spacer shoulders 104-7 on the left fin 104 of the semiconductor structure. As the spacer shoulders 104-7 of the right fin is composed of the same material as the spacer shoulders 104-7 of the left fin, a selective etch of this material may remove the spacer shoulders 104-7 of both fins. Accordingly, before the selective etching, the method may include depositing an OPL 104-15 on the bottom of the right fin 104. In this way, the OPL 104-15 protects the spacer shoulders 104-7 of the right fin 104 from the selective etch.

At operation 248, a fabrication tool can perform backside replacement gate formation and HKMG recess, described with respect to FIGS. 1-25-1, 1-25-2. As stated previously, forming the backside replacement gate can involve removing the OPL 104-15, depositing work function metal 104-16 in the right fin 104, and depositing work function metal 104-17 (different from work function metal 104-16) in the left fin 104. Performing the HKMG recession can involve removing the materials of the exposed dielectric liners 104-14.

At operation 250, a fabrication tool can perform backside contact and backside interconnect formation, described with respect to FIGS. 1-26-1, 1-26-2. As stated previously, forming backside contacts 120B can be similar to the process of forming contacts 120T, 120G. Further, forming the backside interconnect 124 is beyond the scope of this disclosure and not further discussed. As shown, the semiconductor structure includes two stacked FET devices the left stacked FET 126-L and the right stacked FET 126-R. The left stacked FET 126-L includes connected gates, enabling the left stacked FET 126-L to have a different threshold voltage than the right stacked FET 126-R, which does not include connected gates.

The terminology used herein is for the purpose of describing particular embodiments only and is not intended to be limiting of the various embodiments. As used herein, the singular forms “a,” “an,” and “the” are intended to include the plural forms as well, unless the context clearly indicates otherwise. It will be further understood that the terms “includes” and/or “including,” when used in this specification, specify the presence of the stated features, integers, steps, operations, elements, and/or components, but do not preclude the presence or addition of one or more other features, integers, steps, operations, elements, components, and/or groups thereof. In the previous detailed description of example embodiments of the various embodiments, reference was made to the accompanying drawings (where like numbers represent like elements), which form a part hereof, and in which is shown by way of illustration specific example embodiments in which the various embodiments may be practiced. These embodiments were described in sufficient detail to enable those skilled in the art to practice the embodiments, but other embodiments may be used, and logical, mechanical, electrical, and other changes may be made without departing from the scope of the various embodiments. In the previous description, numerous specific details were set forth to provide a thorough understanding the various embodiments. However, the various embodiments may be practiced without these specific details. In other instances, well-known circuits, structures, and techniques have not been shown in detail in order not to obscure embodiments.

As used herein, “a number of” when used with reference to items, means one or more items. For example, “a number of different types of networks” is one or more different types of networks. When different reference numbers comprise a common number followed by differing letters (e.g., 100a, 100b, 100c) or punctuation followed by differing numbers (e.g., 100-1, 100-2, or 100.1, 100.2), use of the reference character only without the letter or following numbers (e.g., 100) may refer to the group of elements as a whole, any subset of the group, or an example specimen of the group.

Further, the phrase “at least one of,” when used with a list of items, means different combinations of one or more of the listed items can be used, and only one of each item in the list may be needed. In other words, “at least one of” means any combination of items and number of items may be used from the list, but not all of the items in the list are required. The item can be a particular object, a thing, or a category. For example, without limitation, “at least one of item A, item B, or item C” may include item A, item A and item B, or item B. This example also may include item A, item B, and item C or item B and item C. Of course, any combinations of these items can be present. In some illustrative examples, “at least one of” can be, for example, without limitation, two of item A; one of item B; and ten of item C; four of item B and seven of item C; or other suitable combinations. Different instances of the word “embodiment” as used within this specification do not necessarily refer to the same embodiment, but they may. Any data and data structures illustrated or described herein are examples only, and in other embodiments, different amounts of data, types of data, fields, numbers and types of fields, field names, numbers and types of rows, records, entries, or organizations of data may be used. In addition, any data may be combined with logic, so that a separate data structure may not be necessary. The previous detailed description is, therefore, not to be taken in a limiting sense.

The descriptions of the various embodiments of the present disclosure have been presented for purposes of illustration but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

Although the present invention has been described in terms of specific embodiments, it is anticipated that alterations and modification thereof will become apparent to one skilled in the art. Therefore, it is intended that the following claims be interpreted as covering all such alterations and modifications as fall within the true spirit and scope of the invention.

What is claimed is:

1. A semiconductor structure comprising:
a first stacked field effect transistor (FET) configured to operate as a shared gate device, and comprising:
a first top FET comprising a first top work-function metal (WFM); and
a first bottom FET comprising a first bottom WFM, wherein the first top WFM and the first bottom WFM are connected through a pair of shared gate connectors disposed on either side of a middle dielectric isolation (MDI) layer; and
a second stacked FET configured to operate as two independent gate devices:
a second top FET comprising a second top WFM; and
a second bottom FET comprising a second bottom WFM, wherein the second top WFM and the second bottom WFM are separated by the MDI layer and a pair of spacer shoulders disposed on either side of the MDI layer.

2. The semiconductor structure of claim 1, further comprising a backside contact for the second bottom FET.

3. The semiconductor structure of claim 1, further comprising a bottom dielectric isolation (BDI) layer composed of a same dielectric as the MDI layer.

4. The semiconductor structure of claim 3, wherein the spacer shoulders comprise a dielectric different from a dielectric of the MDI layer.

5. A semiconductor structure comprising:
a first stacked field effect transistor (FET) configured to operate as a shared gate device, and comprising:
a first top FET comprising a first top work-function metal (WFM); and
a first bottom FET comprising a first bottom WFM, wherein the first top WFM and the first bottom WFM are connected through a pair of shared gate connectors disposed on either side of a middle dielectric isolation (MDI) layer, and wherein the first top WFM is associated with a first top voltage threshold, and wherein the first bottom WFM is associated with a first bottom voltage threshold that is different than the first top voltage threshold; and
a second stacked FET configured to operate as two independent gate devices:
a second top FET comprising a second top WFM; and
a second bottom FET comprising a second bottom WFM, wherein the second top WFM and the second bottom WFM are separated by the MDI layer and a pair of spacer shoulders disposed on either side of the MDI layer, wherein the second top WFM is associated with a second top voltage threshold, and wherein the second bottom WFM is associated with a second bottom voltage threshold that is different than the second top voltage threshold, and wherein:
the first top WFM is formed by depositing the first top WFM through a frontside opening, wherein the frontside opening does not comprise a gate dielectric; and
the second top FET is formed by depositing the second top WFM through the frontside opening.

6. The semiconductor structure of claim 5, wherein:
the first bottom WFM is formed by depositing the first bottom WFM through a backside opening, wherein the backside opening does not comprise a gate dielectric; and
the second bottom FET is formed by depositing the second bottom WFM through the backside opening.

7. The semiconductor structure of claim 5, further comprising a backside contact for the second bottom FET.

8. The semiconductor structure of claim 5, further comprising a bottom dielectric isolation (BDI) layer composed of a same dielectric as the MDI layer.

9. The semiconductor structure of claim 8, wherein the spacer shoulders comprise a dielectric different from a dielectric of the MDI layer.

10. A method for fabricating a semiconductor structure, the method comprising:
forming a bottom dielectric isolation (BDI) layer;
forming a middle dielectric isolation (MDI) layer;
performing an interlayer dielectric fill that prevents access to the BDI layer and MDI layer;
performing a fin reveal that provides access to the MDI layer;
performing a selective MDI indentation on the MDI layer to form a pair of MDI divots, wherein each of the pair of MDI divots is disposed on either end of the MDI layer; and
performing an MDI indentation fill to form a pair of spacer shoulders on the MDI layer, wherein the MDI indentation fill fills the pair of MDI divots with an spacer shoulder dielectric that is different than a dielectric of the MDI.

11. The method of claim 10, further comprising:
forming a first top WFM by depositing a first top WFM through a frontside opening, wherein the frontside opening does not comprise a gate dielectric; and
forming a second top FET by depositing a second top WFM through the frontside opening.

12. The semiconductor structure of claim 10, further comprising:
forming a first bottom WFM by depositing a first bottom WFM through a backside opening, wherein the backside opening does not comprise a gate dielectric; and
forming a second bottom FET by depositing a second bottom WFM through the backside opening.

13. The method of claim 10, further comprising performing a selective channel indentation of a plurality of channel layers of the semiconductor structure to form a pair of channel divots on each of the plurality of channel layers, wherein each of the pair of channel divots is disposed on either end of each of the plurality of channel layers.

14. The method of claim 13, further comprising:
performing a second fin reveal that provides access to the BDI layer; and
performing a selective BDI indentation to form a pair of BDI divots, wherein each of the pair of BDI divots is disposed on either end of the BDI layer.

15. The method of claim 14, further comprising:
performing a silicon-germanium (SiGe) epitaxial growth to generate an SiGe epitaxial that:
surrounds the plurality of channels;
surrounds the pair of spacer shoulders; and
surrounds the BDI layer; and
performing a reactive ion etching (RIE) on the SiGe epitaxial to form a plurality of fins.

16. The method of claim 15, further comprising performing dielectric-based gate formation.

17. The method of claim 16, further comprising:
performing top sacrificial layer removal from a top of the semiconductor structure; and
performing replacement gate formation on the top of the semiconductor structure.

18. The method of claim 17, further comprising:
performing a wafer flip;
performing bottom sacrificial layer removal from a bottom of the semiconductor structure; and
removing the pair of spacer shoulders for a fin to be fabricated into a shared gate device.

19. The method of claim 18, further comprising performing backside replacement gate formation to form:
the shared gate device; and
an independent gate device.

20. The method of claim 19, further comprising forming a bottom gate contact for the independent gate device.
